(19) United States
(12) Patent Application Publication
(10) Pub. No.: US 2021/0162404 A1
(43) Pub. Date: Jun. 3, 2021

(54) FLUID DEVICE

(71) Applicants: The University of Tokyo, Tokyo (JP); NIKON CORPORATION, Tokyo (JP)

(72) Inventors: Takanori ICHIKI, Tokyo (JP); Ryo KOBAYASHI, Kawasaki-shi (JP); Taro UENO, Tokyo (JP)

(21) Appl. No.: 16/770,936

(22) PCT Filed: Dec. 13, 2017
(86) PCT No.: PCT/JP2017/044789

§ 371 Date: Jun. 8, 2020

(51) Int. Cl. B01L 3/00

(52) U.S. Cl. CPC B01L 3/50273; B01L 2300/0883; B01L 2300/08; B01L 2200/0684; B01L 2400/0457

(57) ABSTRACT

A fluidic device that can stably supply a solution from a reservoir without causing bubbles to precede a solution is provided. The fluidic device includes a flow path into which a solution is introduced and a reservoir in which the solution is accommodated and which supplies the solution to the flow path. A length of the reservoir in a direction in which the solution flows toward the flow path is greater than a width perpendicular to the length. A width and a depth of the reservoir are formed in a size based on a capillary length which is calculated on the basis of a surface tension and a density of the solution and acceleration which includes gravity and which is applied to the solution.

### TECHNICAL FIELD

The invention relates to a fluidic device.

### BACKGROUND

Recently, development of micro-total analysis systems (μ-TAS) for the purpose of an increase in speed, an increase in efficiency, and an increase in a degree of integration of tests in the field of in-vitro diagnosis or microminiaturization of test equipment has attracted attention and active study thereof has progressed in the world.

μ-TAS are more excellent than test equipment in the related art in that μ-TAS can measure and analyze a small amount of a sample, can be carried, can be used at a low cost and discarded, and the like.

μ-TAS have attracted attention as a method with high usefulness when a reagent of a high price is used or when small amounts of samples and large numbers of samples are tested.

A device including a flow path and a pump disposed in the flow path has been reported as an element of μ-TAS (Non Patent Document 1). In such a device, a plurality of solutions are mixed in the flow path by injecting the plurality of solutions into the flow path and activating the pump.

### RELATED ART DOCUMENTS

### Patent Document

### [Patent Document 1]

Japanese Unexamined Patent Application, First Publication No. 2005-65607

### [Non Patent Document 1]

Jong Wook Hong, Vincent Studer, Giao Hang, W French Anderson and Stephen R Quake, Nature Biotechnology 22, 435-439 (2004)

### SUMMARY OF INVENTION

According to a first aspect of the present invention, there is provided a fluidic device including: a flow path into which a solution is introduced; and a reservoir in which the solution is accommodated and which supplies the solution to the flow path, wherein a length of the reservoir in a direction in which the solution flows toward the flow path is greater than a width perpendicular to the length, and wherein a width and a depth of the reservoir are formed in a size based on a capillary length which is calculated based on a surface tension and a density of the solution and acceleration which includes gravity and which is applied to the solution.

### BRIEF DESCRIPTION OF THE DRAWINGS

FIG. 1 is a schematic front view of a fluidic device according to an embodiment.

FIG. 2 is a bottom view of a substrate plate 9 according to the embodiment.

FIG. 3 is a cross-sectional view along an A-A line in FIG. 2.

FIG. 4 is a cross-sectional view illustrating an example of a reservoir according to the embodiment.

FIG. 5 is a cross-sectional view illustrating an example of a reservoir according to the embodiment.

FIG. 6 is a cross-sectional view illustrating an example of a reservoir according to the embodiment.

FIG. 7 is a diagram illustrating a relationship between a radius r of a reservoir according to the embodiment and a volume V of a solution maintained therein and a relationship between a capillary rise height and the volume V of a solution maintained therein.

FIG. 8 is a diagram illustrating a relationship between a length of a short side of a reservoir according to the embodiment and a capillary rise height.

FIG. 9 is a partial detailed diagram schematically illustrating a reservoir according to the embodiment.

FIG. 10 is a plan view schematically illustrating the fluidic device according to the embodiment.

FIG. 11 is a plan view schematically illustrating the fluidic device according to the embodiment from the reservoir side.

FIG. 12 is a plan view schematically illustrating the fluidic device according to the embodiment.

FIG. 13 is a bottom view schematically illustrating a reservoir layer according to the embodiment.

FIG. 14 is a plan view schematically illustrating the fluidic device according to the embodiment.

FIG. 15 is a plan view schematically illustrating the fluidic device according to the embodiment.

FIG. 16 is a plan view schematically illustrating the fluidic device according to the embodiment.

FIG. 17 is a plan view schematically illustrating the fluidic device according to the embodiment.

FIG. 18 is a plan view illustrating a modified example of a reservoir according to the embodiment.

### DESCRIPTION OF EMBODIMENTS

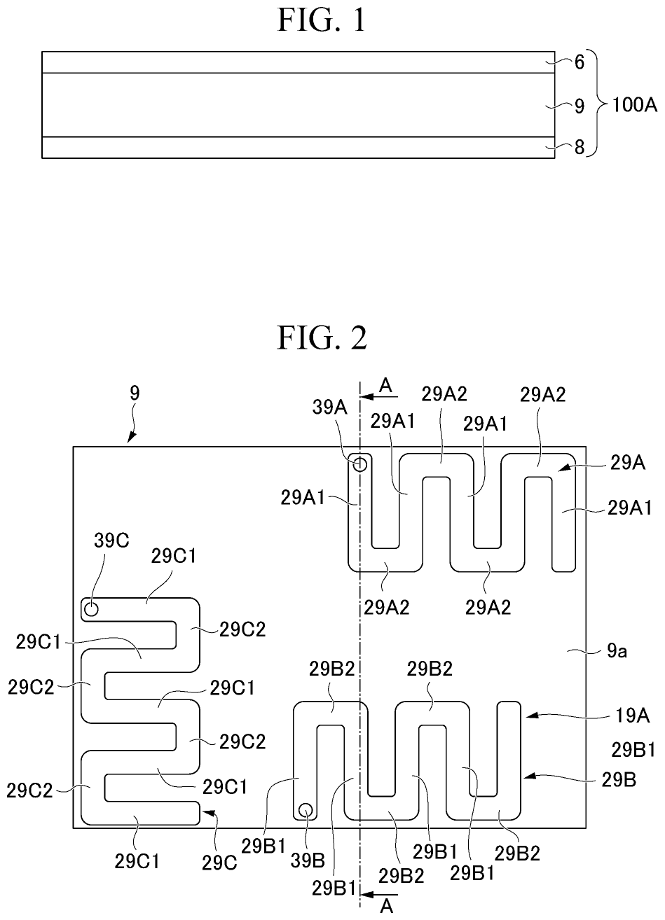

Hereinafter, an embodiment of a fluidic device will be described with reference to FIGS. 1 to 18. In the drawings which are used in the following description, featured parts may be enlarged for the purpose of convenience in order to facilitate understanding of features, and dimensional ratios of elements or the like are not the same as actual ones.

### First Embodiment

FIG. 1 is a front view of a fluidic device 100A according to a first embodiment.

The fluidic device 100A according to this embodiment includes a device that detects a sample material which is a detection target included in a sample by an immune reaction, an enzyme reaction, or the like. Examples of the sample material include biomolecules such as nucleic acid, DNA, RNA, peptides, proteins, and extracellular endoplasmic reticula. The fluidic device 100A includes an upper plate 6, a lower plate 8, and a substrate plate 9. The upper plate 6, the lower plate 8, and the substrate plate 9 are formed of, for example, a resin material (such as polypropylene or polycarbonate).

In the following description, it is assumed that the upper plate (for example, a lid, an upper part or a lower part of a flow path, or a top surface or a bottom surface of a flow path) 6, a lower plate (for example, a lid, an upper part or a lower part of a flow path, or a top surface or a bottom surface of a flow path) 8, and the substrate plate 9 are arranged along a horizontal plane, the upper plate 6 is disposed above the substrate plate 9, and the lower plate 8 is disposed below the substrate plate 9. This is for defining a horizontal direction and a vertical direction for the purpose of convenience of explanation and does not limit directions at the time of use of the fluidic device 100A according to this embodiment.

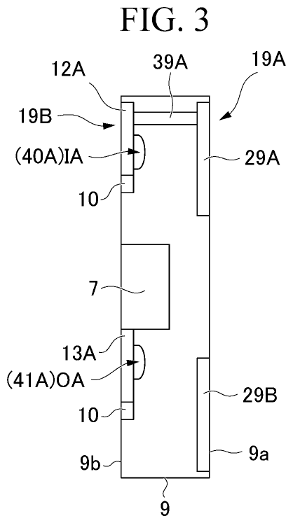

FIG. 2 is a bottom view of the substrate plate 9. In FIG. 2, the shape of the top surface side is not illustrated. FIG. 3 is a sectional view along line A-A in FIG. 2. In FIGS. 1 to 3, an air flow path for discharging or introducing air in a flow path at the time of introduction of the solution is not illustrated.

As illustrated in FIG. 3, the substrate plate 9 includes a reservoir layer 19A on a bottom surface (one surface) 9a side and a reaction layer 19B on a top surface (the other surface) 9b side. The reaction layer 19B includes a circulating flow path 10, introduction flow paths 12A, 12B, and 12C (the introduction flow paths 12B and 12C are not illustrated in FIG. 3), discharge flow paths 13A, 13B, and 13C (the discharge flow paths 13B and 13C are not illustrated in FIG. 3), a waste solution tank 7, introduction valves IA, IB, and IC (the introduction valves IB and IC are not illustrated in FIG. 3), and waste solution valves OA, OB, and OC (the waste solution valves OB and OC are not illustrated in FIG. 3) that are disposed in the top surface 9b of the substrate plate 9.

As illustrated in FIG. 2, the reservoir layer 19A includes a plurality of (three in FIG. 2) flow path type reservoirs 29A, 29B, and 29C which are disposed in the bottom surface 9a of the substrate plate 9 (the reservoir 29C is not illustrated in FIG. 3). A flow path type reservoir is a reservoir which is constituted by a long and thin flow path in which a length is greater than a width. The reservoirs 29A, 29B, and 29C can independently accommodate solutions. The reservoirs 29A, 29B, and 29C are formed of linear recesses (for example, depressions) which are formed in an in-plane direction of the bottom surface 9a (for example, one in-plane direction or a plurality of in-plane directions of the bottom surface 9a, a direction parallel to an in-plane direction of the bottom surface 9a) when the substrate plate 9 is seen from the upper plate 6 side. For example, the reservoirs 29A, 29B, and 29C are spaces which are formed in a tube shape or a tubular shape when the lower plate 8 and the substrate plate 9 are bonded to each other. The bottom surfaces of the recesses in the reservoirs 29A, 29B, and 29C are substantially flush with each other. The recesses in the reservoirs 29A, 29B, and 29C have the same width. A cross-section of each recess has, for example, a rectangular shape. For example, the width of the recesses is 1.5 mm and the depth thereof is 1.5 mm. The volumes of the recesses in the reservoirs 29A, 29B, and 29C are set on the basis of amounts of solutions accommodated therein. For example, the lengths of the reservoirs 29A, 29B, and 29C are set on the basis of the amounts of solutions accommodated therein. The reservoirs 29A, 29B, and 29C in this embodiment have different volumes.

The width and the depth of the recesses are examples, preferably range from 0.1 mm to several tens of mm, and more preferably range from 0.5 mm to several mm. They can be arbitrarily set depending on the size of the fluidic device (a micro-fluidic device or the like) 100A in consideration of a relationship between a capillary force and a surface tension which will be described later.

The reservoirs 29A, 29B, and 29C are formed in a meandering shape in which the linear recess extends in a predetermined direction while being horizontally folded back. Describing the reservoir 29A, the reservoir 29A is formed in a meandering shape including a plurality of (five in FIG. 2) first straight portions 29A1 which are arranged parallel to a predetermined direction (a right-left direction in FIG. 2) and second straight portions 29A2 which repeatedly connect connection portions between ends of the neighboring first straight portions 29A1 alternately at one end and the other end of the first straight portions 29A1. Similarly to the reservoir 29A, the reservoirs 29B and 29C are formed in a meandering shape.

One end of the reservoir 29A is connected to a penetration portion 39A that penetrates the substrate plate 9 in a thickness direction thereof (for example, a direction perpendicular to or crossing the bottom surface 9a or the top surface 9b). The other end of the reservoir 29A is connected to an atmospheric open portion which is not illustrated. The atmospheric open portion may be a penetration portion through which air can flow and which penetrates the substrate plate 9 in the thickness direction with a diameter with which a solution does not leak or a groove portion through which air can flow and which connects the other end of the reservoir 29A to the outside of the substrate plate 9 with a depth with which a solution does not leak. One end of the reservoir 29B is connected to a penetration portion 39B that penetrates the substrate plate 9 in the thickness direction thereof. The other end of the reservoir 29B is connected to an atmospheric open portion which is not illustrated. One end of the reservoir 29C is connected to a penetration portion 39C that penetrates the substrate plate 9 in the thickness direction thereof. The other end of the reservoir 29C is connected to an atmospheric open portion which is not illustrated. The atmospheric open portions connected to the reservoirs 29B and 29C may be penetration portions or groove portions similarly to the reservoir 29A.

For example, when the atmospheric open portions connected to the reservoirs 29A, 29B, and 29C are penetration portions, penetration holes (not illustrated) that penetrate the upper plate 6 in the thickness direction are formed at positions of the upper plate 6 facing the penetration portions to communicate with the penetration portions. The other ends of the reservoirs 29A, 29B, and 29C are open to the atmosphere by communication with the penetration portions and the penetration holes. Since the penetration holes communicating with the reservoirs 29A, 29B, and 29C are open in the top surface of the upper plate 6, a solution can be injected into the reservoirs 29A, 29B, and 29C from the openings.

An introduction flow path 12A is connected to the penetration portion (a penetrating flow path) 39A at one end and is connected to a circulating flow path 10 from the outside at the other end. For example, the introduction flow path 12A and the reservoir 29A partially overlap each other in a top view (for example, when seen from the upper side in a stacking direction of the upper plate 6, the lower plate 8, and the substrate plate 9) and are connected to each other via the penetration portion 39A disposed in the overlap part.

An introduction flow path 12B is connected to the penetration portion 39B at one end and is connected to the circulating flow path 10 from the outside at the other end. For example, the introduction flow path 12B and the reservoir 29B partially overlap each other in a top view (for example, when seen from the upper side in a stacking direction of the upper plate 6, the lower plate 8, and the substrate plate 9) and are connected to each other via the penetration portion 39B disposed in the overlap part.

An introduction flow path 12C is connected to the penetration portion 39C at one end and is connected to the circulating flow path 10 from the outside at the other end. For example, the introduction flow path 12C and the reservoir 29C partially overlap each other in a top view (for example, when seen from the upper side in a stacking direction of the upper plate 6, the lower plate 8, and the substrate plate 9) and are connected to each other via the penetration portion 39C disposed in the overlap part.

For example, in the substrate plate 9, since the introduction flow paths 12A, 12B, and 12C and the reservoirs 29A, 29B, and 29C and are connected to each other via the penetration portions 39A, 39B, and 39C which are provided in the parts in which they overlap each other, a distance between each introduction flow path and the corresponding reservoir (for example, a distance that a solution flows) decreases and a pressure loss when the solution is introduced into the introduction flow path from each reservoir decreases, and therefore a solution can be easily and rapidly introduced.

Here, when the solutions accommodated in the reservoirs 29A, 29B, and 29C are introduced into the introduction flow paths 12A, 12B, and 12C via the penetration portions 39A, 39B, and 39C, the solutions need to be introduced into the introduction flow path 12A, 12B, and 12C without allowing bubbles accommodated in the reservoirs 29A, 29B, and 29C to precede the solutions. For example, when negative-pressure suction of the introduction flow paths 12A, 12B, and 12C is performed in a state in which the surface including the reservoirs 29A, 29B, and 29C is inclined with respect to the horizontal plane, bubbles accommodated in the reservoirs 29A, 29B, and 29C may precede solutions and be introduced into the introduction flow paths 12A, 12B, and 12C on the basis of a relative relationship between an influence of a capillary force on a solution and an influence of acceleration which includes the gravity and which is applied to the solution. For example, when reagents accommodated in the reservoirs 29A, 29B, and 29C are introduced into the introduction flow paths 12A, 12B, and 12C, air may be sent from air introduction ports (not illustrated) at an end opposite to the penetration portions 39A, 39B, and 39C in the reservoirs 29A, 29B, and 29C to transfer the reagents. The reservoirs 29A, 29B, and 29C may not be filled with solutions but air (gas) may be included at one end or both ends of the flow path. In this case, when air precedes the solution at the time of transferring the solution, the solution which is a continuous body is cut off by the bubbles. When solutions into which bubbles are mixed are introduced into the introduction flow paths 12A, 12B, and 12C, reactions such as quantification, mixing, agitation, and detection in a flow path 11 which will be described later are hindered.

The relative relationship between an influence of a capillary force on a solution and an influence of acceleration which includes the gravity and which is applied to the solution is expressed by a capillary length which is calculated on the basis of a surface tension and a density of solutions accommodated in the reservoirs 29A, 29B, and 29C and acceleration which includes the gravity and which is applied to the solution. When the surface tension of a solution is defined as γ (N/m), the density of a solution is defined as ρ (kg/m³), and the acceleration which includes the gravity and which is applied to a solution is defined as G (m/s²), the capillary length κ^{-I} is calculated according to Expression (1).

κ⁻¹=(γ/(ρ×G))^{1/2} (1)

When a representative length of the recesses in the reservoirs 29A, 29B, and 29C is greater than the capillary length which is calculated according to Expression (1), the acceleration which includes the gravity and which is applied to the solutions has a greater influence on the solutions of the reservoirs 29A, 29B, and 29C than the capillary force does. In this case, for example, when the surface including the reservoirs 29A, 29B, and 29C is inclined with respect to the horizontal plane, the solutions are not held by the surface tensions and interfaces between the reservoirs 29A, 29B, and 29C and the solutions collapse. Accordingly, bubbles accommodated in the reservoirs 29A, 29B, and 29C are introduced into the introduction flow paths 12A, 12B, and 12C to precede the solutions.

On the other hand, when the representative length of the recesses is less than the capillary length calculated according to Expression (1), the capillary force has a greater influence on the solutions accommodated in the reservoirs 29A, 29B, and 29C than the acceleration which includes the gravity and which is applied to the solutions does. In this case, even when the surface including the reservoirs 29A, 29B, and 29C is inclined with respect to the horizontal plane, the solutions can be held by the surface tensions, the interfaces between the reservoirs 29A, 29B, and 29C and the solutions do not collapse, and the solutions are introduced into the introduction flow paths 12A, 12B, and 12C without allowing bubbles accommodated in the reservoirs 29A, 29B, and 29C to precede the solutions held in the recesses with the capillary force.

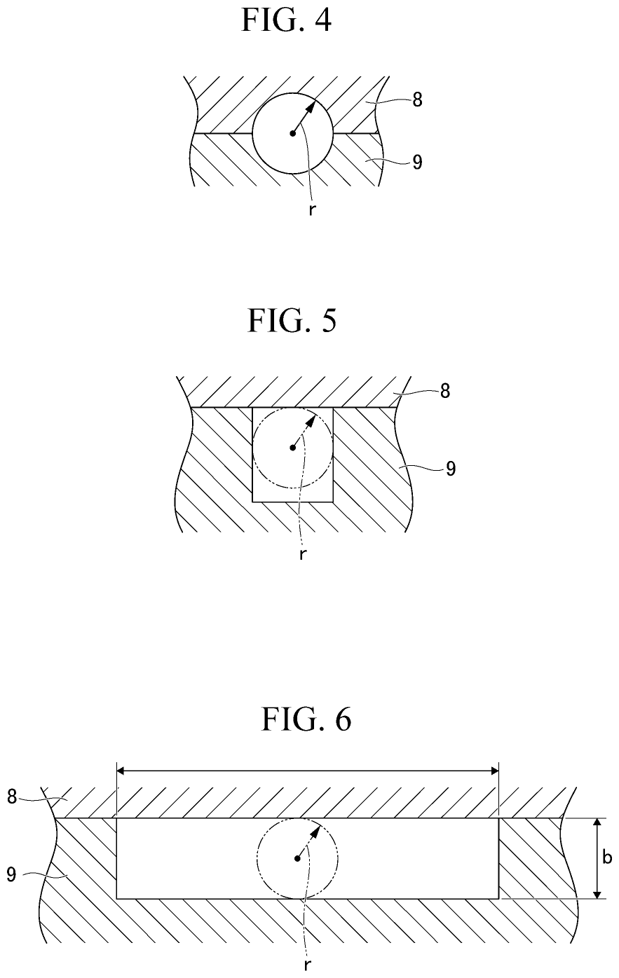

Accordingly, a width and a depth of the recesses in the reservoirs 29A, 29B, and 29C are set to magnitudes based on the capillary length which is calculated on the basis of the surface tensions and the densities of the accommodated solutions and the acceleration which includes the gravity and which is applied to the solutions. FIGS. 4 to 6 are sectional views along the width direction in the reservoirs 29A, 29B, and 29C. In FIGS. 4 to 6, the upper and lower sides in FIG. 1 are reversed.

FIG. 4 illustrates an example in which cross-sections of the reservoirs 29A, 29B, and 29C are circular. FIGS. 5 and 6 illustrate an example in which the cross-sections of the reservoirs 29A, 29B, and 29C are rectangular. When a radius of an inscribed circle on the cross-section along the width direction in the reservoirs 29A, 29B, and 29C is defined as r (m) as illustrated in FIGS. 4 and 5, the radius r is set to a value satisfying Expression (2).

0.05×10⁻³<r<(γ/(ρ×G))^{1/2} (2)

When the radius r of the inscribed circle on each cross-section of the reservoirs 29A, 29B, and 29C is less than (γ/(ρ×G))^{1/2}, the capillary force has a greater influence on the solutions accommodated in the reservoirs 29A, 29B, and 29C than the acceleration which includes the gravity and which is applied to the solutions does as described above and thus it is possible to introduce the solutions into the introduction flow paths 12A, 12B, and 12C without allowing bubbles accommodated in the reservoirs 29A, 29B, and 29C to precede the solutions.

When the radius r of the inscribed circle on each cross-section of the reservoirs 29A, 29B, and 29C is greater than 0.05×10⁻³ (m), it is possible to improve molding accuracy when the substrate plate 9 is mass-produced, for example, by injection molding and to decrease volume unevenness of a reagent tank. Since a volume proportion of a flow path wall surface increases relatively, it is possible to increase an amount of reagent which can be held in a constant space.

As the acceleration G which includes the gravity and which is applied to the solution, the gravitational acceleration g (about 9.80865 m/s²) can be used when acceleration other than the gravity is not applied to the fluidic device 100A (the reservoirs 29A, 29B, and 29C) but, for example, about G=6×g (m/s²) can be used when external acceleration is considered. The value of the acceleration G can be appropriately set to a value corresponding to a measurement environment using the fluidic device 100A.

A maximum value of a liquid column holding height (a solution holding length) L (m) in which solutions in the reservoirs 29A, 29B, and 29C are held with the capillary force is expressed by Expression (3), where a cross-sectional area of the reservoirs 29A, 29B, and 29C is defined as A (m²), a receding contact angle of the solutions in the reservoirs 29A, 29B, and 29C is defined as α(°), an advancing contact angle is defined as β(°), and a flow path wetted perimeter length is defined as Wp (m).

L=(γ×Wp×(cos α−cos β))/(ρ×A×G) (3)

In Expression (3), a contact angle at which the length L is maximized includes the receding contact angle α=0° and the advancing contact angle β=180°. Accordingly, when a solution with the receding contact angle α=0° and the advancing contact angle β=180° is used, a length (a reagent length) L in which the solution is held in the reservoirs 29A, 29B, and 29C is expressed by Expression (3′).

L≤(2×γ×Wp)/(ρ×A×G) (3′)

A maximum value of a volume V (m³) of a solution which is held in each of the reservoirs 29A, 29B, and 29C is approximately expressed by Expression (4) when the cross-sectional shape of the reservoirs 29A, 29B, and 29C is circular as illustrated in FIG. 4.

V=(2π×r×γ×(cos α−cos β))/(ρ×G) (4)

When the cross-sectional shape of the reservoirs 29A, 29B, and 29C is rectangular as illustrated in FIGS. 5 and 6, the maximum value of the liquid column holding height L (m) is expressed by Expression (5), where the longer length of the width and the depth is defined as a and the shorter length is defined as b.

L=(2×(a+b)×γ×(cos α−cos β))/(ρ×a×b×G) (5)

The maximum value of a volume V (m³) of a solution which is held in each of the reservoirs 29A, 29B, and 29C is expressed by Expression (6).

V=(2×(a+b)×γ×(cos α−cos β))/(ρ×G) (6)

When a>>B is satisfied, the maximum value of a volume V (m³) of a solution is approximately expressed by Expression (6′)

V=(2×a×γ×(cos α−cos β))/(ρ×G) (6′)

For example, when the density ρ of a solution accommodated in each of the reservoirs 29A, 29B, and 29C with a circular cross-section is 1000 (kg/m³), the surface tension γ is 0.0728 (N/m), and the acceleration G when it is assumed that only the gravity is applied to the solution is 9.80665 (m/s²: gravitational acceleration), the radius r in Expression (2) needs to be set to 2.7246 (mm) which is the maximum radius in order to introduce the solution into the introduction flow paths 12A, 12B, and 12C without allowing bubbles accommodated in the reservoirs 29A, 29B, and 29C to precede the solution. When the acceleration G applied to the solution is 6×9.80665 (m/s²) in consideration of external acceleration applied to the fluidic device 100A during transportation of the fluidic device 100A, the radius r in Expression (2) needs to be set to 1.1123 (mm) which is the maximum radius in order to introduce the solution into the introduction flow paths 12A, 12B, and 12C without allowing bubbles accommodated in the reservoirs 29A, 29B, and 29C to precede the solution (when the cross-section is rectangular, the maximum value of the width is about 2.22 (mm)) When the flow path radius and the flow path width of the reservoirs 29A, 29B, and 29C satisfy these conditions, it is possible to prevent mixing of bubbles into the solution due to preceding of the bubbles even when acceleration equal to or greater than the gravity is applied due to vibration, acceleration, deceleration, impact, fall, or the like at the time of transportation of the micro fluidic device 100A in a state in which the solution and the bubbles are included in the reservoirs 29A, 29B, and 29C. Even when the micro fluidic device 100A is used during transportation, it is possible to prevent mixing of bubbles into the solution due to preceding of the bubbles. Accordingly, it is possible to prevent an influence of bubbles on reactions such as quantification, mixing, agitation, and detection in the flow path 11 which will be described later.

In the following description, the maximum radius which is acquired on the basis of Expression (2) is appropriately referred to as a capillary radius.

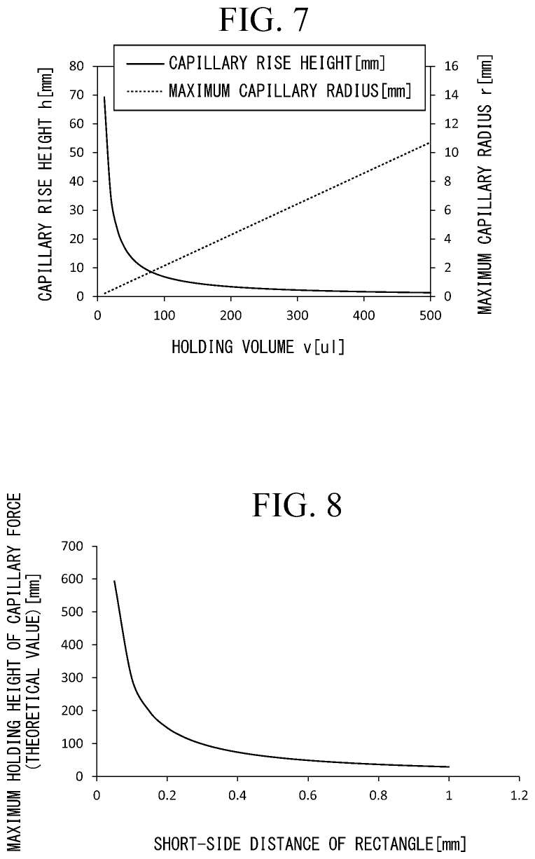

FIG. 7 is a diagram illustrating a relationship between the radius r (mm) of each of the reservoirs 29A, 29B, and 29C and the volume V (μL) of a solution held in the reservoirs 29A, 29B, and 29C which is acquired on the basis of Expression (4) and a relationship between the liquid column holding height L (m) and the volume V (μL) of the solution held in each of the reservoirs 29A, 29B, and 29C which is acquired on the basis of Expression (3), where the solution has the density ρ and the surface tension γ which are exemplified above. In Expressions (3) and (4), the receding contact angle α is 0(°), the advancing contact angle β is 180(°), and the acceleration G includes only the gravitational acceleration.

The maximum volume V of the solution which can be held in the reservoirs 29A, 29B, and 29C is acquired from the maximum value of the liquid column holding height L acquired from Expression (3). A minimum liquid column holding height L (m) can be acquired from the acquired maximum volume V of the solution. Accordingly, by setting the radius r on the basis of the density ρ, the surface tension γ, the receding contact angle α, and the advancing contact angle β of a solution accommodated in each of the reservoirs 29A, 29B, and 29C with a circular cross-section and the acceleration G which is applied to the solution, it is possible to set the maximum value of the liquid column holding height L and the maximum value of the volume V in which a solution can be introduced into each of the introduction flow paths 12A, 12B, and 12C without allowing bubbles to precede the solution. Table 2 describes Reference Examples 31 to 55 when the cross-section is circular.

TABLE 1

| | | | | α | β | | | |
|---|---|---|---|---|---|---|---|---|
| | | g | γ | Receding | Advancing | | | |
| | ρ | gravitational | Surface | contact | contact | | | |
| | density | acceleration | tension | angle | angle | r | L | V |
| | [kg/m³] | [m/s²] | [N/m] | [°] | [°] | [mm] | [mm] | [mm³] |
| Reference | 1000 | 9.80665 | 0.0728 | 0 | 180 | 0.02 | 1484.707 | 1.865738 |
| Example 1 | | | | | | | | |
| Reference | 1000 | 9.80665 | 0.0728 | 0 | 180 | 0.04 | 742.3534 | 3.731475 |
| Example 2 | | | | | | | | |
| Reference | 1000 | 9.80665 | 0.0728 | 0 | 180 | 0.06 | 494.9023 | 5.597213 |
| Example 3 | | | | | | | | |
| Reference | 1000 | 9.80665 | 0.0728 | 0 | 180 | 0.08 | 371.1767 | 7.46295 |
| Example 4 | | | | | | | | |
| Reference | 1000 | 9.80665 | 0.0728 | 0 | 180 | 0.1 | 296.9414 | 9.328688 |
| Example 5 | | | | | | | | |
| Reference | 1000 | 9.80665 | 0.0728 | 0 | 180 | 0.12 | 247.4511 | 11.19443 |
| Example 6 | | | | | | | | |
| Reference | 1000 | 9.80665 | 0.0728 | 0 | 180 | 0.14 | 212.101 | 13.06016 |
| Example 7 | | | | | | | | |
| Reference | 1000 | 9.80665 | 0.0728 | 0 | 180 | 0.16 | 185.5884 | 14.9259 |
| Example 8 | | | | | | | | |
| Reference | 1000 | 9.80665 | 0.0728 | 0 | 180 | 0.18 | 164.9674 | 16.79164 |
| Example 9 | | | | | | | | |
| Reference | 1000 | 9.80665 | 0.0728 | 0 | 180 | 0.2 | 148.4707 | 18.65738 |
| Example 10 | | | | | | | | |
| Reference | 1000 | 9.80665 | 0.0728 | 0 | 180 | 0.22 | 134.9733 | 20.52311 |
| Example 11 | | | | | | | | |
| Reference | 1000 | 9.80665 | 0.0728 | 0 | 180 | 0.24 | 123.7256 | 22.38885 |
| Example 12 | | | | | | | | |
| Reference | 1000 | 9.80665 | 0.0728 | 0 | 180 | 0.26 | 114.2082 | 24.25459 |
| Example 13 | | | | | | | | |
| Reference | 1000 | 9.80665 | 0.0728 | 0 | 180 | 0.28 | 106.0505 | 26.12033 |
| Example 14 | | | | | | | | |
| Reference | 1000 | 9.80665 | 0.0728 | 0 | 180 | 0.3 | 98.98045 | 27.98606 |
| Example 15 | | | | | | | | |
| Reference | 1000 | 9.80665 | 0.0728 | 0 | 180 | 0.32 | 92.79418 | 29.8518 |
| Example 16 | | | | | | | | |
| Reference | 1000 | 9.80665 | 0.0728 | 0 | 180 | 0.34 | 87.33569 | 31.71754 |
| Example 17 | | | | | | | | |
| Reference | 1000 | 9.80665 | 0.0728 | 0 | 180 | 0.36 | 82.48371 | 33.58328 |
| Example 18 | | | | | | | | |
| Reference | 1000 | 9.80665 | 0.0728 | 0 | 180 | 0.38 | 78.14246 | 35.44901 |
| Example 19 | | | | | | | | |
| Reference | 1000 | 9.80665 | 0.0728 | 0 | 180 | 0.4 | 74.23534 | 37.31475 |
| Example 20 | | | | | | | | |
| Reference | 1000 | 9.80665 | 0.0728 | 0 | 180 | 0.42 | 70.70032 | 39.18049 |
| Example 21 | | | | | | | | |
| Reference | 1000 | 9.80665 | 0.0728 | 0 | 180 | 0.44 | 67.48667 | 41.04623 |
| Example 22 | | | | | | | | |
| Reference | 1000 | 9.80665 | 0.0728 | 0 | 180 | 0.46 | 64.55247 | 42.91196 |
| Example 23 | | | | | | | | |
| Reference | 1000 | 9.80665 | 0.0728 | 0 | 180 | 0.48 | 61.86278 | 44.7777 |
| Example 24 | | | | | | | | |
| Reference | 1000 | 9.80665 | 0.0728 | 0 | 180 | 0.5 | 59.38827 | 46.64344 |
| Example 25 | | | | | | | | |
| Reference | 1000 | 9.80665 | 0.0728 | 0 | 180 | 0.75 | 39.59218 | 69.96516 |
| Example 26 | | | | | | | | |
| Reference | 1000 | 9.80665 | 0.0728 | 0 | 180 | 0.8 | 37.11767 | 74.6295 |
| Example 27 | | | | | | | | |
| Reference | 1000 | 9.80665 | 0.0728 | 0 | 180 | 1 | 29.69414 | 93.29688 |
| Example 28 | | | | | | | | |
| Reference | 1000 | 9.80665 | 0.0728 | 0 | 180 | 1.5 | 19.79609 | 139.9303 |
| Example 29 | | | | | | | | |
| Reference | 1000 | 9.80665 | 0.0728 | 0 | 180 | 2 | 14.84707 | 186.5738 |
| Example 30 | | | | | | | | |

In Table 1, the capillary radius r (mm), the maximum value (mm) of the liquid column holding height L, and the maximum volume V (mm³) are described.

FIG. 8 is a diagram illustrating a relationship between the length of the short side b (mm) of each of the reservoirs 29A, 29B, and 29C with a rectangular cross-section and the liquid column holding height L which is acquired on the basis of Expression (5), where a solution has the density ρ and the surface tension γ which are exemplified above. In Expression (5), the receding contact angle α is 0(°), the advancing contact angle β is 180(°), and the acceleration G includes only the gravitational acceleration. The length b (mm) is calculated on the basis of Expression (2). As illustrated in FIG. 8, the maximum value of the liquid column holding height L can be acquired from the length b (mm) calculated on the basis of the capillary length and Expression (5). The maximum volume V of the solution which can be held in each of the reservoirs 29A, 29B, and 29C is acquired from the acquired maximum value of the liquid column holding height L and Expression (6).

Accordingly, by setting the length b on the basis of the density ρ, the surface tension γ, the receding contact angle α, and the advancing contact angle β of a solution accommodated in each of the reservoirs 29A, 29B, and 29C with a rectangular cross-section and the acceleration G which is applied to the solution, it is possible to set the maximum value of the liquid column holding height L and the maximum value of the volume V in which a solution can be introduced into each of the introduction flow paths 12A, 12B, and 12C without allowing bubbles to precede the solution. Table 1 describes Reference Examples 1 to 30 when the cross-section is rectangular.

TABLE 2

| | | | | α | β | | |
|---|---|---|---|---|---|---|---|
| | | g | γ | Receding | Advancing | | |
| | ρ | gravitational | Surface | contact | contact | | |
| | density | acceleration | tension | angle | angle | b | L |
| | [kg/m³] | [m/s²] | [N/m] | [°] | [°] | [mm] | [mm] |
| Reference | 1000 | 9.80665 | 0.0728 | 0 | 180 | 0.05 | 593.8827 |
| Example 31 | | | | | | | |
| Reference | 1000 | 9.80665 | 0.0728 | 0 | 180 | 0.1 | 296.9414 |
| Example 32 | | | | | | | |
| Reference | 1000 | 9.80665 | 0.0728 | 0 | 180 | 0.15 | 197.9609 |
| Example 33 | | | | | | | |
| Reference | 1000 | 9.80665 | 0.0728 | 0 | 180 | 0.2 | 148.4707 |
| Example 34 | | | | | | | |
| Reference | 1000 | 9.80665 | 0.0728 | 0 | 180 | 0.25 | 118.7765 |
| Example 35 | | | | | | | |
| Reference | 1000 | 9.80665 | 0.0728 | 0 | 180 | 0.3 | 98.98045 |
| Example 36 | | | | | | | |
| Reference | 1000 | 9.80665 | 0.0728 | 0 | 180 | 0.35 | 84.84039 |
| Example 37 | | | | | | | |
| Reference | 1000 | 9.80665 | 0.0728 | 0 | 180 | 0.4 | 74.23534 |
| Example 38 | | | | | | | |
| Reference | 1000 | 9.80665 | 0.0728 | 0 | 180 | 0.45 | 65.98697 |
| Example 39 | | | | | | | |
| Reference | 1000 | 9.80665 | 0.0728 | 0 | 180 | 0.5 | 59.38827 |
| Example 40 | | | | | | | |
| Reference | 1000 | 9.80665 | 0.0728 | 0 | 180 | 0.55 | 53.98934 |
| Example 41 | | | | | | | |
| Reference | 1000 | 9.80665 | 0.0728 | 0 | 180 | 0.6 | 49.49023 |
| Example 42 | | | | | | | |
| Reference | 1000 | 9.80665 | 0.0728 | 0 | 180 | 0.65 | 45.68329 |
| Example 43 | | | | | | | |
| Reference | 1000 | 9.80665 | 0.0728 | 0 | 180 | 0.7 | 42.42019 |
| Example 45 | | | | | | | |
| Reference | 1000 | 9.80665 | 0.0728 | 0 | 180 | 0.75 | 39.59219 |
| Example 46 | | | | | | | |
| Reference | 1000 | 9.80665 | 0.0728 | 0 | 180 | 0.8 | 37.11767 |
| Example 47 | | | | | | | |
| Reference | 1000 | 9.80665 | 0.0728 | 0 | 180 | 0.85 | 34.93428 |
| Example 48 | | | | | | | |
| Reference | 1000 | 9.80665 | 0.0728 | 0 | 180 | 0.9 | 32.99348 |
| Example 49 | | | | | | | |
| Reference | 1000 | 9.80665 | 0.0728 | 0 | 180 | 0.95 | 31.25699 |
| Example 50 | | | | | | | |
| Reference | 1000 | 9.80665 | 0.0728 | 0 | 180 | 1 | 29.69414 |
| Example 51 | | | | | | | |
| Reference | 1000 | 9.80665 | 0.0728 | 0 | 180 | 1.5 | 19.79609 |
| Example 52 | | | | | | | |
| Reference | 1000 | 9.80665 | 0.0728 | 0 | 180 | 2 | 14.84707 |
| Example 53 | | | | | | | |
| Reference | 1000 | 9.80665 | 0.0728 | 0 | 180 | 3. | 9.898045 |
| Example 54 | | | | | | | |
| Reference | 1000 | 9.80665 | 0.0728 | 0 | 180 | 4 | 7.423534 |
| Example 55 | | | | | | | |

In Table 2, the short-side length b (mm) and the maximum value of the liquid column holding height L (mm) are described.

There is a likelihood that bubbles accommodated in the reservoirs 29A, 29B, and 29C will be introduced into the introduction flow paths 12A, 12B, and 12C to precede the solution when the cross-sectional size of the reservoirs 29A, 29B, and 29C is set on the basis of an amount of reagent which is used without considering the capillary length as described above and the surface including the reservoirs 29A, 29B, and 29C is inclined with respect to the horizontal plane, and there is a likelihood that a problem with a decrease in solution which can be held therein will occur when the cross-sectional size of the reservoirs 29A, 29B, and 29C is decreased.

For example, Patent Document 1 describes that a flow path type is preferable such that a reagent does not remain in the reagent tank. However, in fact, when the reagent tank is of a flow path type but the cross-sectional area of the flow path is large, there is a problem in that bubbles precede a liquid. Therefore, the reservoir in this embodiment is a flow path type reservoir which is developed in a shape in which the cross-sectional area of the flow path is maximized to increase an amount of reagent which can be held and bubbles do not precede.

That is, in the fluidic device 100A according to this embodiment, since the width and the depth of each of the reservoirs 29A, 29B, and 29C are set to magnitudes based on the capillary length, it is possible to introduce a solution into the introduction flow paths 12A, 12B, and 12C without allowing bubbles accommodated in the reservoirs 29A, 29B, and 29C to precede the solution. In the fluidic device 100A according to this embodiment, it is possible to hold a maximum amount of solution which can be accommodated in the reservoirs 29A, 29B, and 29C by setting the width and the depth of each of the reservoirs 29A, 29B, and 29C on the basis of the capillary length.

### Second Embodiment

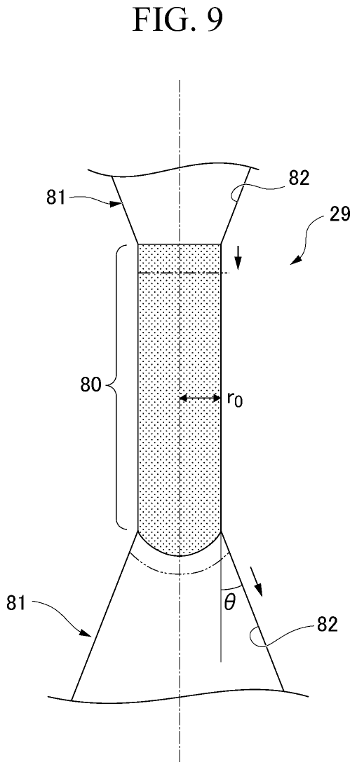

A fluidic device 100A according to a second embodiment will be described below with reference to FIG. 9. In the drawing, the same elements as the elements in the first embodiment illustrated in FIGS. 1 to 8 will be referred to by the same reference signs and description thereof will be omitted.

FIG. 9 is a partially detailed diagram schematically illustrating a reservoir 29. The reservoir 29 is representative of the above-mentioned reservoirs 29A, 29B, and 29C.

As illustrated in FIG. 9, the reservoir 29 includes a holding region 80 that holds a solution S in the maximum value of a liquid holding length L which is calculated according to Expression (3) or (3′). Diameter-increased portions 81 are provided outside of both ends in the length direction of the holding region 80. The width of each diameter-increased portion 81 increases gradually from the width of the holding region 80 outward in the length direction. The flow path wetted perimeter length of each diameter-increased portion 81 increases gradually from the flow path wetted perimeter length in the holding region 80 outward in the length direction. The cross-sectional area of each diameter-increased portion 81 increases gradually from the cross-sectional area in the holding region 80 outward in the length direction.

Each diameter-increased portion 81 includes a side surface 82 in which the diameter increases outward. The side surface 82 is inclined by an angle θ about the length direction of the holding region 80.

In the reservoir 29 having the above-mentioned configuration, when the holding region 80 is disposed in the vertical direction and a solution is accommodated in the holding region 80 in a length L greater than the maximum length (liquid column holding height) L0 which is calculated according to Expression (3′), the solution with a length ΔL which is represented by ΔL=L−L0 cannot be held with the surface tension.

In the reservoir 29 according to this embodiment, since the solution accommodated in the length ΔL cannot be held with the surface tension, a lower wetted interface moves downward when the holding region 80 is disposed in the vertical direction and an upper wetted interface moves downward a distance dx at acceleration including the gravity. Here, since the diameter-increased portion 81 of which a wetted area increases with a gradual increase of the flow path wetted perimeter length downward is disposed below (outside of) the holding region 80 and the surface tension increases more than that in the holding region 80, the solution moving from the holding region 80 to the diameter-increased portion 81 is held in a state in which the holding length and the holding volume are greater than those in the holding region 80.

Here, work δ·W1 on the upper interface of the solution when the solution in the holding region 80 moves downward a distance dx at acceleration including the gravity is expressed by Expression (7), where the cross-sectional area of the holding region 80 is defined as A1 (m²).

δ·W1=γ×ΔA1 (7)

Work δ·W1 on the lower interface of the solution is expressed by Expression (8), where the cross-sectional area of the holding region 80 is defined as A2 (m²).

δ·W2=γ×ΔA2 (8)

Virtual work ΔW on the upper and lower interfaces is calculated according to Expression (9) based on Expressions (7) and (8).

ΔW=δ·W2−δ·W1=γ×(ΔA2−ΔA1) (9)

Expression (10) is acquired from the balance between the virtual work calculated according to Expression (9) and potential energy of the solution in the length ΔL based on the acceleration including the gravity.

((ρ×A×G×ΔL)×dx=γ×(ΔA2−ΔA1) (10)

Here, ΔA2−ΔA1 is approximately calculated according to Expression (11).

ΔA2−ΔA1=Wp×((1+tan²θ)^{1/2}−1)×dx (11)

The length ΔL is calculated according to Expression (12) based on Expressions (10) and (11).

ΔL=γ×Wp×((1+tan²θ)^{1/2}−1)/(ρ×A×G) (12)

The volume ΔV of the solution with the length ΔL is calculated according to Expression (13).

ΔV=γ×Wp×((1+tan²θ)^{1/2}−1)/(ρ×G) (13)

(Cross-Section of Reservoir 29 is Circular)

When the cross-section of the reservoir 29 is circular and the radius in the holding region 80 is r0, Wp=2×π×r0 is satisfied and the cross-sectional area in the holding region 80 is A=2×π×r02. Accordingly, on the basis of Expressions (12) and (13), the length ΔL is calculated according to Expression (14) and the volume ΔV is calculated according to Expression (15).

ΔL=2×γ×((1+tan²θ)^{1/2}−1)/(ρ×r0×G) (14)

ΔV=2×π×r0×γ×((1+tan²θ)^{1/2}−1)/(ρ×G) (15)

Reference Examples 56 to 68 in which the cross-section is circular are described in Table 3.

TABLE 3

| | | | | | α | β | | liquid | | | | |
|---|---|---|---|---|---|---|---|---|---|---|---|---|
| | | | g | γ | Receding | Advancing | | column | | | | Increased |
| | angle | ρ | gravitational | Surface | contact | contact | | holding | | Increased | Ratio of | volume |
| | θ | density | acceleration | tension | angle | angle | r0 | length L | | length | increase | ΔV |
| | [°] | [kg/m³] | [m/s²] | [N/m] | [°] | [°] | [mm] | [mm] | coefficient | ΔL | [%] | [μl] |
| Reference | 0 | 1000 | 9.80665 | 0.0728 | 0 | 180 | 0.5 | 59.38827 | 0 | 0 | 0 | 0 |
| Example 56 | | | | | | | | | | | | |
| Reference | 5 | 1000 | 9.80665 | 0.0728 | 0 | 180 | 0.5 | 59.38827 | 0.00382 | 0.113427 | 0.19 | 0.089085 |
| Example 57 | | | | | | | | | | | | |
| Reference | 10 | 1000 | 9.80665 | 0.0728 | 0 | 180 | 0.5 | 59.38827 | 0.015427 | 0.45808 | 0.77 | 0.359775 |
| Example 58 | | | | | | | | | | | | |
| Reference | 15 | 1000 | 9.80665 | 0.0728 | 0 | 180 | 0.5 | 59.38827 | 0.035276 | 1.047496 | 1.76 | 0.822701 |
| Example 59 | | | | | | | | | | | | |
| Reference | 20 | 1000 | 9.80665 | 0.0728 | 0 | 180 | 0.5 | 59.38827 | 0.064178 | 1.905704 | 3.21 | 1.496736 |
| Example 60 | | | | | | | | | | | | |
| Reference | 25 | 1000 | 9.80665 | 0.0728 | 0 | 180 | 0.5 | 59.38827 | 0.103378 | 3.069718 | 5.17 | 2.410951 |
| Example 61 | | | | | | | | | | | | |
| Reference | 30 | 1000 | 9.80665 | 0.0728 | 0 | 180 | 0.5 | 59.38827 | 0.154701 | 4.593699 | 7.74 | 3.607883 |
| Example 62 | | | | | | | | | | | | |
| Reference | 35 | 1000 | 9.80665 | 0.0728 | 0 | 180 | 0.5 | 59.38827 | 0.220775 | 6.555711 | 11.04 | 5.148843 |
| Example 63 | | | | | | | | | | | | |
| Reference | 40 | 1000 | 9.80665 | 0.0728 | 0 | 180 | 0.5 | 59.38827 | 0.305407 | 9.068806 | 15.27 | 7.122623 |
| Example 64 | | | | | | | | | | | | |
| Reference | 45 | 1000 | 9.80665 | 0.0728 | 0 | 180 | 0.5 | 59.38827 | 0.414214 | 12.29971 | 20.71 | 9.660173 |
| Example 65 | | | | | | | | | | | | |
| Reference | 50 | 1000 | 9.80665 | 0.0728 | 0 | 180 | 0.5 | 59.38827 | 0.555724 | 16.50174 | 27.79 | 12.96044 |
| Example 66 | | | | | | | | | | | | |
| Reference | 55 | 1000 | 9.80665 | 0.0728 | 0 | 180 | 0.5 | 59.38827 | 0.743447 | 22.07601 | 37.17 | 17.33846 |
| Example 67 | | | | | | | | | | | | |
| Reference | 60 | 1000 | 9.80665 | 0.0728 | 0 | 180 | 0.5 | 59.38827 | 1 | 29.69414 | 50 | 23.32172 |
| Example 68 | | | | | | | | | | | | |

In Table 3, ((1+tan²θ)^{1/2}−1) in Expressions (14) and (15) is described as “coefficient.”

As described in Table 3, it was ascertained that the length ΔL and the volume ΔV in Reference Examples 57 to 68 in which the flow path wetted perimeter length increases are greater than those in Reference Example 56 with an angle 0° in which no diameter-increased portion 81 is provided. As described in Table 3, it was ascertained that the length ΔL and the volume ΔV increase as the angle θ increases.

(Cross-Section of Reservoir 29 is Rectangular)

When the cross-section of the reservoir 29 is rectangular, the width in the holding region 80 is w (m), and the depth (height) is h (m), Wp=2×(w+h) is satisfied and the cross-sectional area in the holding region 80 is A=w×h. Accordingly, on the basis of Expressions (12) and (13), the length ΔL is calculated according to Expression (16) and the volume ΔV is calculated according to Expression (17).

ΔL=2×γ×(w+h)×((1+tan²θ)^{1/2}−1)/(ρ×w×h×G) (16)

ΔV=2×γ×(w+h)×((1+tan²θ)^{1/2}−1)/(ρ×G) (17)

Reference Examples 69 to 81 when the cross-section is rectangular are described in Table 4.

TABLE 4

| | | | | | α | β | | | liquid | | | | |
|---|---|---|---|---|---|---|---|---|---|---|---|---|---|
| | | | g | γ | Receding | Advancing | | | column | | | | |
| | angle | ρ | gravitational | Surface | contact | contact | depth | width | holding | | Increased | Ratio of | Increased |
| | θ | density | acceleration | tension | angle | angle | h | w | length L | | length | increase | volume |
| | [°] | [kg/m³] | [m/s²] | [N/m] | [°] | [°] | [mm] | [mm] | [mm] | coefficient | ΔL | [%] | ΔV |
| Reference | 0 | 1000 | 9.80665 | 0.0728 | 0 | 180 | 1 | 1 | 59.38827 | 0 | 0 | 0 | 0 |
| Example 69 | | | | | | | | | | | | | |
| Reference | 5 | 1000 | 9.80665 | 0.0728 | 0 | 180 | 1 | 1 | 59.38827 | 0.00382 | 0.113427 | 0.19 | 0.113427 |
| Example 70 | | | | | | | | | | | | | |
| Reference | 10 | 1000 | 9.80665 | 0.0728 | 0 | 180 | 1 | 1 | 59.38827 | 0.015427 | 0.45808 | 0.77 | 0.45808 |
| Example 71 | | | | | | | | | | | | | |
| Reference | 15 | 1000 | 9.80665 | 0.0728 | 0 | 180 | 1 | 1 | 59.38827 | 0.035276 | 1.047496 | 1.76 | 1.047496 |
| Example 72 | | | | | | | | | | | | | |
| Reference | 20 | 1000 | 9.80665 | 0.0728 | 0 | 180 | 1 | 1 | 59.38827 | 0.064178 | 1.905704 | 3.21 | 1.905704 |
| Example 73 | | | | | | | | | | | | | |
| Reference | 25 | 1000 | 9.80665 | 0.0728 | 0 | 180 | 1 | 1 | 59.38827 | 0.103378 | 3.069718 | 5.17 | 3.069718 |
| Example 74 | | | | | | | | | | | | | |
| Reference | 30 | 1000 | 9.80665 | 0.0728 | 0 | 180 | 1 | 1 | 59.38827 | 0.154701 | 4.593699 | 7.74 | 4.593699 |
| Example 75 | | | | | | | | | | | | | |
| Reference | 35 | 1000 | 9.80665 | 0.0728 | 0 | 180 | 1 | 1 | 59.38827 | 0.220775 | 6.555711 | 11.04 | 6.555711 |
| Example 76 | | | | | | | | | | | | | |
| Reference | 40 | 1000 | 9.80665 | 0.0728 | 0 | 180 | 1 | 1 | 59.38827 | 0.305407 | 9.068806 | 15.27 | 9.068806 |
| Example 77 | | | | | | | | | | | | | |
| Reference | 45 | 1000 | 9.80665 | 0.0728 | 0 | 180 | 1 | 1 | 59.38827 | 0.414214 | 12.29971 | 20.71 | 12.29971 |
| Example 78 | | | | | | | | | | | | | |
| Reference | 50 | 1000 | 9.80665 | 0.0728 | 0 | 180 | 1 | 1 | 59.38827 | 0.555724 | 16.50174 | 27.79 | 16.50174 |
| Example 79 | | | | | | | | | | | | | |
| Reference | 55 | 1000 | 9.80665 | 0.0728 | 0 | 180 | 1 | 1 | 59.38827 | 0.743447 | 22.07601 | 37.17 | 22.07601 |
| Example 80 | | | | | | | | | | | | | |
| Reference | 60 | 1000 | 9.80665 | 0.0728 | 0 | 180 | 1 | 1 | 59.38827 | 1 | 29.69414 | 50 | 29.69414 |
| Example 81 | | | | | | | | | | | | | |

In Table 4, ((1+tan²θ)^{1/2}−1) in Expressions (16) and (17) is described as “coefficient.”

As described in Table 4, it was ascertained that the length ΔL and the volume ΔV in Reference Examples 70 to 81 in which the flow path wetted perimeter length increases are greater than those in Reference Example 69 with an angle 0° in which no diameter-increased portion 81 is provided. As described in Table 4, it was ascertained that the length ΔL and the volume ΔV increase as the angle θ increases.

Expressions (16) and (17) are provided for a configuration in which the angle θ of the side surfaces in the direction of the width w and the side surfaces in the direction of the depth (height) h in the reservoir 29 increases biaxially in the diameter-increased portion 81, but may be provided for a configuration in which the angle θ increases uniaxially in the direction of the width w or the direction of the depth (height) h.

For example, when the angle θ increases uniaxially in the direction of the depth (height) h, the length ΔL is calculated according to Expression (18) and the volume ΔV is calculated according to Expression (19).

ΔL=2×γ×((1+tan²θ)^{1/2}−1)/(ρ×w×G) (18)

ΔV=2×γ×h×((1+tan²θ)^{1/2}−1)/(ρ×G) (19)

As can be clearly seen from the result of comparison between Expressions (16) and (18) and the result of comparison between Expressions (17) and (19), it was ascertained that the length ΔL and the volume ΔV in the configuration in which the angle θ increases biaxially are greater than those in the configuration in which the angle θ increases uniaxially.

As described above, in the fluidic device 100A according to this embodiment, it is possible to obtain the same operations and advantages as in the first embodiment and to easily increase the length and the volume of a solution which can be held by the reservoir 29 even when acceleration including the gravity is applied thereto by disposing the diameter-increased portions 81 outside of the holding region 80. In the fluidic device 100A according to this embodiment, by disposing the diameter-increased portions 81 outside of both ends of the holding region 80, it is possible to hold a solution in the reservoir 29 in a state in which the length and the volume of the solution are increased even when the fluidic device 100A is inclined in any direction.

### Third Embodiment

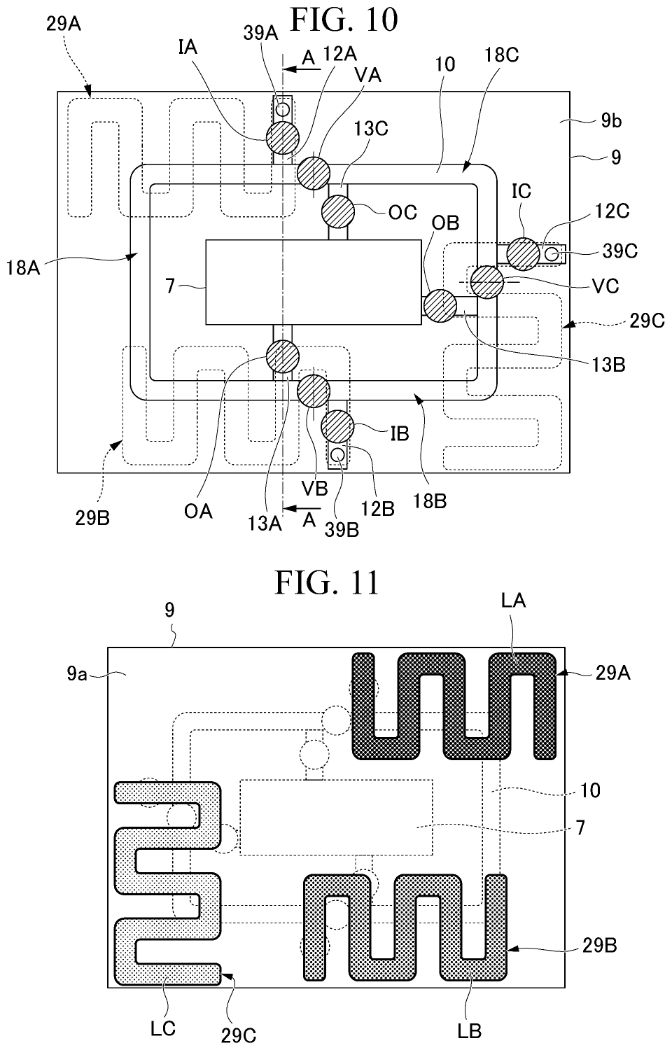

A fluidic device 100A according to a third embodiment will be described below with reference to FIGS. 10 and 11. In the drawings, the same elements as the elements in the first embodiment illustrated in FIGS. 1 to 8 will be referred to by the same reference signs and description thereof will be omitted.

FIG. 10 is a diagram schematically illustrating a fluidic device 100A and is a plan view (a top view) of the substrate plate 9 when seen from the upper plate 6.

As illustrated in FIG. 10, a reaction layer 19B includes a circulating flow path 10, introduction flow paths 12A, 12B, and 12C, discharge flow path 13A, 13B, and 13C, a waste solution tank 7, quantification valves VA, VB, and VC, introduction valves IA, IB, and IC, and waste solution valves OA, OB, and OC which are disposed in the top surface 9b of the substrate plate 9.

The quantification valves VA, VB, and VC are arranged such that sections of the circulating flow path 10 which are partitioned by the quantification valves have a predetermined volume. For example, the quantification valves VA, VB, and VC partition the circulating flow path 10 into a first quantification section 18A, a second quantification section 18B, and a second quantification section 18C.

A position at which the introduction flow path 12A is connected to the circulating flow path 10 is close to the quantification valve VA in the first quantification section 18A.

A position at which the introduction flow path 12B is connected to the circulating flow path 10 is close to the quantification valve VB in the second quantification section 18B.

A position at which the introduction flow path 12C is connected to the circulating flow path 10 is close to the quantification valve VC in the third quantification section 18C.

The introduction valve IA is disposed between a penetration portion 39A in the introduction flow path 12A and the circulating flow path 10. The introduction valve IA includes a semi-spherical recess 40A (see FIG. 3) that divides the introduction flow path 12A and is disposed in the substrate plate 9 and a deformable portion (not illustrated) that is disposed in the upper plate 6 to face the recess 40A and is elastically deformed to close the introduction flow path 12A when it comes into contact with the recess 40A and to open the introduction flow path 12A when it is separated away from the recess 40A. The introduction valve IB is disposed between a penetration portion 39B in the introduction flow path 12B and the circulating flow path 10. The introduction valve IB includes a recess (not illustrated and referred to as a recess 40B for the purpose of convenience) that divides the introduction flow path 12B and has the same shape as the recess 40A disposed in the substrate plate 9 and a deformable portion (not illustrated) that is disposed in the upper plate 6 to face the recess 40B and is elastically deformed to close the introduction flow path 12B when it comes into contact with the recess 40B and to open the introduction flow path 12B when it is separated away from the recess 40B. The introduction valve IC is disposed between a penetration portion 39C in the introduction flow path 12C and the circulating flow path 10. The introduction valve IC includes a recess (not illustrated and referred to as a recess 40C for the purpose of convenience) that divides the introduction flow path 12C and has the same shape as the recess 40A disposed in the substrate plate 9 and a deformable portion (not illustrated) that is disposed in the upper plate 6 to face the recess 40C and is elastically deformed to close the introduction flow path 12C when it comes into contact with the recess 40C and to open the introduction flow path 12C when it is separated away from the recess 40C.

As illustrated in FIGS. 10 and 3, for example, the waste solution tank 7 is disposed in an inside region of the circulating flow path 10. Accordingly, it is possible to achieve a decrease in size of the fluidic device 100A. A tank suction hole (not illustrated) that is open to the waste solution tank 7 is disposed in the upper plate 6 to penetrate the upper plate 6 in the thickness direction thereof.

The discharge flow path 13A is a flow path that is used to discharge a solution in the first quantification section 18A in the circulating flow path 10 to the waste solution tank 7. One end of the discharge flow path 13A is connected to the circulating flow path 10. A position at which the discharge flow path 13A is connected to the circulating flow path 10 is close to the quantification valve VB in the first quantification section 18A. The other end of the discharge flow path 13A is connected to the waste solution tank 7. The discharge flow path 13B is a flow path that is used to discharge a solution in the second quantification section 18B in the circulating flow path 10 to the waste solution tank 7. One end of the discharge flow path 13B is connected to the circulating flow path 10. A position at which the discharge flow path 13B is connected to the circulating flow path 10 is close to the quantification valve VC in the second quantification section 18B. The other end of the discharge flow path 13B is connected to the waste solution tank 7. The discharge flow path 13C is a flow path that is used to discharge a solution in the third quantification section 18C in the circulating flow path 10 to the waste solution tank 7. One end of the discharge flow path 13C is connected to the circulating flow path 10. A position at which the discharge flow path 13C is connected to the circulating flow path 10 is close to the quantification valve VA in the third quantification section 18C. The other end of the discharge flow path 13C is connected to the waste solution tank 7.

The waste solution valve OA is disposed in the halfway (for example, in an intermediate part close to the circulating flow path 10) of the discharge flow path 13A. The waste solution valve OA includes a semi-spherical recess 41A (see FIG. 3) that divides the discharge flow path 13A and is disposed in the substrate plate 9 and a deformable portion (not illustrated) that is disposed in the upper plate 6 to face the recess 41A and is elastically deformed to close the discharge flow path 13A when it comes into contact with the recess 41A and to open the discharge flow path 13A when it is separated away from the recess 41A. The waste solution valve OB is disposed in the halfway (for example, in an intermediate part close to the circulating flow path 10) of the discharge flow path 13B. The waste solution valve OB includes a recess (not illustrated and referred to as a recess 41B) that divides the discharge flow path 13B and has the same shape as the recess 41A disposed in the substrate plate 9 and a deformable portion (not illustrated) that is disposed in the upper plate 6 to face the recess 41B and is elastically deformed to close the discharge flow path 13B when it comes into contact with the recess 41B and to open the discharge flow path 13B when it is separated away from the recess 41B. The waste solution valve OC is disposed in the halfway (for example, in an intermediate part close to the circulating flow path 10) of the discharge flow path 13C. The waste solution valve OC includes a recess (not illustrated and referred to as a recess 41C) that divides the discharge flow path 13C and has the same shape as the recess 41A disposed in the substrate plate 9 and a deformable portion (not illustrated) that is disposed in the upper plate 6 to face the recess 41C and is elastically deformed to close the discharge flow path 13C when it comes into contact with the recess 41C and to open the discharge flow path 13C when it is separated away from the recess 41C.

The fluidic device 100A having the above-mentioned configuration is manufactured by forming the circulating flow path, the introduction flow paths, the reservoirs, the penetration portions, and the like in the substrate plate 9, forming and installing the valves in the substrate plate 9 and the upper plate 6, and then bonding and integrating the upper plate 6, the lower plate 8, and the substrate plate 9 by a bonding means such as adhesion (for example, the configuration illustrated in FIG. 1). FIG. 11 is a plan view schematically illustrating the fluidic device 100A when seen from the reservoir side. As illustrated in FIG. 11, a solution LA is accommodated in the reservoir 29A of the manufactured fluidic device 100A, a solution LB is accommodated in the reservoir 29B, and a solution LC is accommodated in the reservoir 29C.

The cross-sectional shape of each of the reservoirs 29A, 29B, and 29C is, for example, rectangular as illustrated in FIG. 5. The cross-section of each of the reservoirs 29A, 29B, and 29C is formed in a size based on the capillary length as described above. The size of the cross-section of each of the reservoirs 29A, 29B, and 29C is set to a size in which the volumes of the solutions LA, LB, and LC required for performing a mixing/reaction can be secured on the basis of the capillary length.

Injection of the solutions LA, LB, and LC into the reservoirs 29A, 29B, and 29C is performed, for example, from openings of penetration holes formed in the upper plate 6. At the time of injection of the solutions LA, LB, and LC into the reservoirs 29A, 29B, and 29C, the reservoirs 29A, 29B, and 29C can be easily filled with the solutions LA, LB, and LC by performing negative-pressure suction from an air hole communicating with one end of each of the reservoirs 29A, 29B, and 29C. In this way, for example, the upper plate 6 forms various types of flow paths described above along with the recesses formed in the substrate plate 9 and is together used to decrease leakage of a solution and to form flow paths. For example, the lower plate 8 forms various types of reservoirs described above along with the recesses formed in the substrate plate 9 and is together used to decrease leakage of a solution and to form flow paths.

The fluidic device 100A can be transported to a place (for example, a test agency, a hospital, a home, or a vehicle) in which a mixing/reaction of the solutions LA, LB, and LC is performed in a state in which the solution LA is accommodated in the reservoir 29A, the solution LB is accommodated in the reservoir 29B, and the solution LC is accommodated in the reservoir 29C.

A routine of performing a mixing/reaction of the solutions LA, LB, and LC using the fluidic device 100A will be described below on the basis of FIGS. 1 to 11. First, a routine of introducing the solution LA into the first quantification section 18A and quantifying the solution LA will be described.

First, the quantification valves VA and VB of the circulating flow path 10 are closed, the waste solution valves OB and OC of the discharge flow paths 13B and 13C are closed, and the waste solution valve OA of the discharge flow path 13A and the introduction valve IA of the introduction flow path 12A are opened. Accordingly, in the circulating flow path 10, the first quantification section 18A is partitioned from the second quantification section 18B and the third quantification section 18C. The waste solution tank 7 is shielded from the discharge flow paths 13B and 13C and is open to and connected to the first quantification section 18A of the circulating flow path 10 via the discharge flow path 13A. The reservoir 29A is open to and connected to the first quantification section 18A of the circulating flow path 10 via the penetration portion 39A and the introduction flow path 12A.

In this state, by performing negative-pressure suction on the waste solution tank 7 from a tank suction hole, the solution LA accommodated in the reservoir 29A is sequentially introduced into the penetration portion 39A, the introduction flow path 12A, the first quantification section 18A of the circulating flow path 10, the discharge flow path 13A, and the waste solution tank 7. There is a likelihood that foreign substance will remain in the flow paths through which the solution LA is introduced into the waste solution tank 7, but since the foreign substance is caught by an introduction head of the solution LA and is introduced into the waste solution tank 7 at the time of introduction of the solution, it is possible to curb the likelihood that the foreign substance will remain in the circulating flow path 10.

In the reservoir 29A, air exists at the other end opposite to the accommodated solution LA (the side opposite to a portion connected to the penetration portion 39A). Accordingly, when the solution LA accommodated in the reservoir 29A is introduced into the circulating flow path 10, for example, there is a likelihood that the fluidic device 100A will be inclined with respect to the horizontal plane and will take a posture in which the penetration portion 39A connected to one end of the linear reservoir 29A is located upside and the other end opposite thereto is located downside. At this time, since the capillary force has a greater influence on the solution LA than the acceleration which includes the gravity and is applied to the solution does and the solution LA is held in the reservoir 29A by the capillary force, the solution can be introduced into the introduction flow path 12A without allowing bubbles remaining at the other end of the reservoir 29A to precede the solution.

Accordingly, it is possible to prevent bubbles from reaching the penetration portion 39A earlier than the solution LA. As illustrated in FIGS. 2 and 11, since the first straight portion 29A1 and the second straight portion 29A2 in the reservoir 29A are alternately and continuously connected and bent, bubbles are likely to gather in the bent portion and can be further prevented from reaching the penetration portion 39A earlier than the solution LA.

Then, the waste solution valve OA and the introduction valve TA are closed in a state in which the introduction head of the solution LA flows into the waste solution tank 7 and the introduction tail remains in the introduction flow path 12A. Accordingly, the solution LA can be quantified on the basis of the volume of the first quantification section 18A. As described above, since the solution LA in the introduction head in which there is a likelihood foreign substance will exist is discharged to the waste solution tank 7 and bubbles remain in the reservoir 29A, the solution LA into which foreign substance or bubbles are not mixed is quantified in the first quantification section 18A of the circulating flow path 10.

Then, in order to introduce the solution LB into the second quantification section 18B and to quantify the solution LB, first, the quantification valves VB and VC of the circulating flow path 10 are closed, the waste solution valves OA and OC of the discharge flow paths 13A and 13C are closed, and the waste solution valve OB of the discharge flow path 13B and the introduction valve IB of the introduction flow path 12B are opened. Accordingly, in the circulating flow path 10, the second quantification section 18B is partitioned from the first quantification section 18A and the third quantification section 18C. The waste solution tank 7 is shielded from the discharge flow paths 13A and 13C and is open to and connected to the second quantification section 18B of the circulating flow path 10 via the discharge flow path 13B. The reservoir 29B is open to and connected to the second quantification section 18B of the circulating flow path 10 via the penetration portion 39B and the introduction flow path 12B.

In this state, by performing negative-pressure suction on the waste solution tank 7 from the tank suction hole, the solution LB accommodated in the reservoir 29B is sequentially introduced into the penetration portion 39B, the introduction flow path 12B, the second quantification section 18B of the circulating flow path 10, the discharge flow path 13B, and the waste solution tank 7. Regarding the solution LB, since the foreign substance remaining in the flow paths through which the solution LB is introduced into the waste solution tank 7 is caught by an introduction head of the solution LB and is introduced into the waste solution tank 7 at the time of introduction of the solution, it is possible to curb the likelihood that the foreign substance will remain in the circulating flow path 10.

In the reservoir 29B, since the capillary force has a greater influence on the solution LB than the acceleration which includes the gravity and is applied to the solution does and the solution LB is held in the reservoir 29B by the capillary force, the solution can be introduced into the introduction flow path 12B without allowing bubbles remaining at the other end of the reservoir 29B to precede the solution. As illustrated in FIGS. 2 and 11, since the first straight portion 29B1 and the second straight portion 29B2 in the reservoir 29B are alternately and continuously connected and bent, bubbles are likely to gather in the bent portion and can be further prevented from reaching the penetration portion 39B earlier than the solution LB.

Then, the waste solution valve OB and the introduction valve IB are closed in a state in which the introduction head of the solution LB flows into the waste solution tank 7 and the introduction tail remains in the introduction flow path 12B. Accordingly, the solution LB can be quantified on the basis of the volume of the second quantification section 18B. As described above, since the solution LB in the introduction head in which there is a likelihood foreign substance will exist is discharged to the waste solution tank 7 and bubbles remain in the reservoir 29B, the solution LB into which foreign substance or bubbles are not mixed is quantified in the second quantification section 18B of the circulating flow path 10.

Then, in order to introduce the solution LC into the third quantification section 18C and to quantify the solution LC, first, the quantification valves VA and VC of the circulating flow path 10 are closed, the waste solution valves OA and OB of the discharge flow paths 13A and 13B are closed, and the waste solution valve OC of the discharge flow path 13C and the introduction valve IC of the introduction flow path 12C are opened. Accordingly, in the circulating flow path 10, the third quantification section 18C is partitioned from the first quantification section 18A and the second quantification section 18B. The waste solution tank 7 is shielded from the discharge flow paths 13A and 13B and is open to and connected to the third quantification section 18C of the circulating flow path 10 via the discharge flow path 13C. The reservoir 29C is open to and connected to the third quantification section 18C of the circulating flow path 10 via the penetration portion 39C and the introduction flow path 12C.

In this state, by performing negative-pressure suction on the waste solution tank 7 from the tank suction hole, the solution LC accommodated in the reservoir 29C is sequentially introduced into the penetration portion 39C, the introduction flow path 12C, the third quantification section 18C of the circulating flow path 10, the discharge flow path 13C, and the waste solution tank 7. Regarding the solution LC, since the foreign substance remaining in the flow paths through which the solution LC is introduced into the waste solution tank 7 is caught by an introduction head of the solution LC and is introduced into the waste solution tank 7 at the time of introduction of the solution, it is possible to curb the likelihood that the foreign substance will remain in the circulating flow path 10.

In the reservoir 29C, since the capillary force has a greater influence on the solution LC than the acceleration which includes the gravity and is applied to the solution does and the solution LC is held in the reservoir 29C by the capillary force, the solution can be introduced into the introduction flow path 12C without allowing bubbles remaining at the other end of the reservoir 29C to precede the solution. As illustrated in FIGS. 2 and 11, since the first straight portion 29C1 and the second straight portion 29C2 in the reservoir 29C are alternately and continuously connected and bent, bubbles are likely to gather in the bent portion and can be prevented from reaching the penetration portion 39C earlier than the solution LC.

Then, the waste solution valve OC and the introduction valve IC are closed in a state in which the introduction head of the solution LC flows into the waste solution tank 7 and the introduction tail remains in the introduction flow path 12C. Accordingly, the solution LC can be quantified on the basis of the volume of the third quantification section 18C. As described above, since the solution LC in the introduction head in which there is a likelihood foreign substance will exist is discharged to the waste solution tank 7 and bubbles remain in the reservoir 29C, the solution LC into which foreign substance or bubbles are not mixed is quantified in the third quantification section 18C of the circulating flow path 10.

When the solutions LA, LB, and LC are quantified and introduced into the circulating flow path 10, the solutions LA, LB, and LC in the circulating flow path 10 are pumped and circulated using a pump. The flow rates of the solutions LA, LB, and LC circulating in the circulating flow path 10 are low in the vicinity of the wall surface and are high at the center of the flow path by interactions (friction) between the flow path wall surface in the flow path and the solutions. As a result, since the flow rates of the solutions LA, LB, and LC are distributed, mixing of the solutions is promoted. For example, by driving a pump, convection occurs in the solutions LA, LB, and LC in the circulating flow path 10 and mixing of a plurality of solutions LA, LB, and LC is promoted. A pump valve that can pump a solution by opening and closing the valves may be used as the pump.

As described above, in the fluidic device 100A according to this embodiment, since the reservoirs 29A, 29B, and 29C are formed of linear recesses which are formed in an in-plane direction of the bottom surface 9a and the size of the cross-section of each of the reservoirs 29A, 29B, and 29C is set on the basis of the capillary length, it is possible to prevent bubbles in the reservoirs 29A, 29B, and 29C from reaching and entering the circulating flow path 10 earlier than the solutions LA, LB, and LC do even when the fluidic device 100A is inclined with respect to the horizontal plane. Accordingly, in the fluidic device 100A according to this embodiment, the solutions LA, LB, and LC can be easily supplied from the reservoirs 29A, 29B, and 29C to the circulating flow path 10. In the fluidic device 100A according to this embodiment, since the reservoirs 29A, 29B, and 29C are bent and meander, the solutions LA, LB, and LC with sufficient volumes can be accommodated therein even when they are formed of linear recesses, bubbles can be easily trapped in the bent portions, and mixing of bubbles into the circulating flow path 10 can be further prevented.

In the embodiment, a routine of sequentially introducing the solutions LA, LB, and LC into the first quantification section 18A, the second quantification section 18B, and the third quantification section 18C has been described above, but the invention is not limited to this routine and a routine of simultaneously introducing the solutions LA, LB, and LC into the first quantification section 18A, the second quantification section 18B, and the third quantification section 18C may be employed.

When this routine is employed, the solutions LA, LB, and LC can be simultaneously quantified and introduced into the first quantification section 18A, the second quantification section 18B, and the third quantification section 18C, respectively, by closing the quantification valves VA, VB, and VC to partition the first quantification section 18A, the second quantification section 18B, and the third quantification section 18C, opening the waste solution valves OA, OB, and OC and the introduction valves IA, IB, and IC, and then performing negative-pressure suction from the tank suction hole on the inside of the waste solution tank 7.

A system according to an embodiment includes the fluidic device 100A and a control unit which is not illustrated. The control unit is connected to the valves (the quantification valves VA, VB, and VC, the introduction valves IA, IB, and IC, and the waste solution valves OA, OB, and OC) which are provided in the fluidic device 100A via connection lines which are not illustrated and controls opening and closing of the valves. With the system according to this embodiment, mixing in the fluidic device 100A can be performed.

### Fourth Embodiment

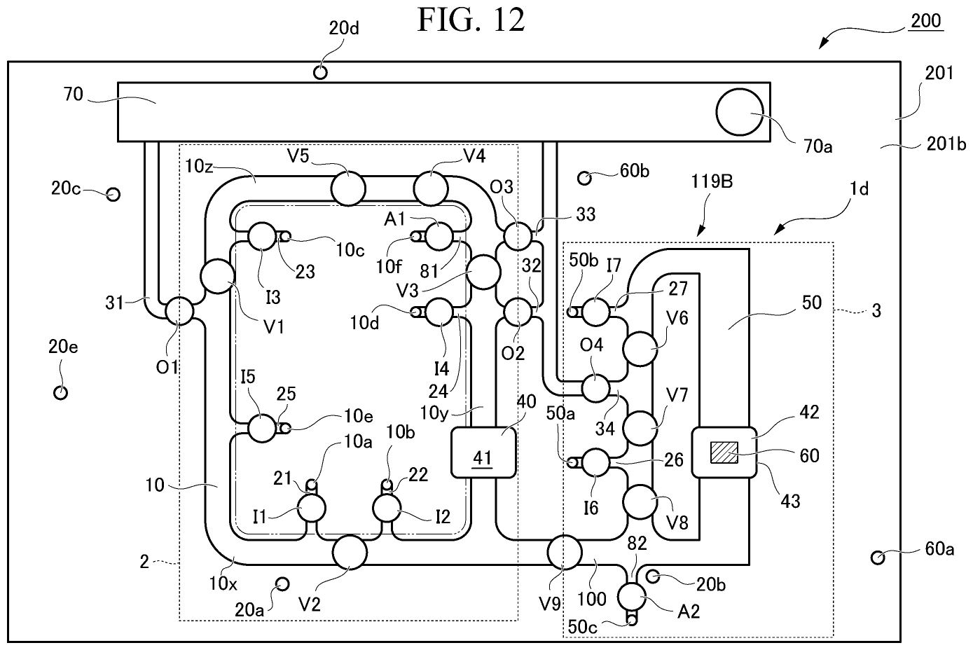

A fluidic device according to a fourth embodiment will be described below with reference to FIGS. 12 to 17. In the drawings, the same elements as the elements in the first to third embodiments illustrated in FIGS. 1 to 11 will be referred to by the same reference signs and description thereof will be omitted.

FIG. 12 is a plan view schematically illustrating a fluidic device 200 according to the fourth embodiment. The fluidic device 200 is a device that detects an antigen (such as a sample material or a biomolecule) which is a detection target included in a test sample by an immune reaction and an enzyme reaction. The fluidic device 200 includes a substrate plate 201 in which flow paths and valves are formed. FIG. 12 schematically illustrating a reaction layer 119B on a top surface 201b side of the substrate plate 201. Part of the reaction layer 119B is formed on the bottom surface side of the upper plate 6, but is described to be formed in the substrate plate 201 other than the upper plate 6.

The fluidic device 200 includes a circulation type mixer 1d. The circulation type mixer 1d includes a first circulating portion 2 in which a solution including carrier particles circulates and a second circulating portion 3 in which a solution introduced from the circulating flow path 10 circulates. The first circulating portion 2 includes a circulating flow path 10 in which a solution including carrier particles circulates, circulating flow path valves V1, V2, and V3, and a capturing portion 40. The second circulating portion 3 includes a second circulating flow path 50 in which a solution introduced from the circulating flow path circulates, a capturing portion 42 that is provided in the second circulating flow path 50, and a detection portion 60 that is provided in the second circulating flow path 50 and detects a sample material which is coupled to the carrier particles. In the first circulating portion 2, pretreatment for detecting the sample material can be performed by circulating the sample material in the circulating flow path 10 to be coupled to the carrier particles and a detection assisting material (for example, a marker material). The pretreated sample material is transferred from the first circulating portion 2 to the second circulating portion 3. In the second circulating portion 3, the pretreated sample material is detected in the second circulating flow path 50. The pretreated sample material repeatedly comes into contact with the detection portion 60 by circulating in the second circulating flow path 50 and is efficiently detected.

The capturing portion 40 includes a capturing means installing portion 41 that is provided in the circulating flow path 10 and in which a capturing means capturing carrier particles can be installed. The carrier particles are, for example, particles which can react with a sample material which is a detection target. Examples of the carrier particles which are used in this embodiment include magnetic beads, magnetic particles, gold nanoparticles, agarose beads, and plastic beads. Examples of the sample material include biomolecules such as nucleic acid, DNA, RNA, peptides, proteins, and extracellular endoplasmic reticula. Examples of the reaction between the carrier particles and the sample material include coupling between the carrier particles and the sample material, adsorption between the carrier particles and the sample material, modification of the carrier particles by the sample material, and chemical change of the carrier particles by the sample material. For example, when magnetic beads or magnetic particles are used as the carrier particles, a magnetic force source such as a magnet can be exemplified as the capturing means. Examples of another capturing means include a column with a filler material which can be coupled to the carrier particles and an electrode which can attract the carrier particles.

The detection portion 60 is disposed to face the capturing portion 42 such that the sample material coupled to the carrier particles captured in the capturing portion 42 having the same configuration as the capturing portion 40 can be detected.

Introduction flow paths 21, 22, 23, 24, and 25 for introducing first to fifth solutions are connected to the circulating flow path 10. Introduction flow path valves I1, I2, I3, I4, and I5 that open and close the introduction flow paths are provided in the introduction flow paths 21, 22, 23, 24, and 25. An introduction flow path 81 that introduces (or discharges) air is connected to the circulating flow path 10, and an introduction flow path valve A1 that opens and closes the introduction flow path is provided in the introduction flow path 81. Discharge flow paths 31, 32, and 33 are connected to the circulating flow path 10. Discharge flow path valves O1, O2, and O3 that open and close the discharge flow paths are provided in the discharge flow paths 31, 32, and 33. A first circulating flow path valve V1, a second circulating flow path valve V2, and a third circulating flow path valve V3 that partition the circulating flow path 10 are provided in the circulating flow path 10. The first circulating flow path valve V1 is disposed in the vicinity of a connecting portion between the discharge flow path 31 and the circulating flow path 10. The second circulating flow path valve V2 is disposed between a connecting portion between the introduction flow path 21 and the circulating flow path 10 and a connecting portion between the introduction flow path 22 and the circulating flow path 10 and in the vicinity thereof. The third circulating flow path valve V3 is disposed between a connecting portion between the discharge flow path 32 and the circulating flow path 10 and a connecting portion between the discharge flow path 33 and the circulating flow path 10 and in the vicinity thereof.

In this way, the circulating flow path 10 are partitioned into three flow paths 10x, 10y, and 10z when the first circulating flow path valve V1, the second circulating flow path valve V2, and the third circulating flow path valve V3 are closed, and at least one introduction flow path and at least one discharge flow path are connected to each section.

Introduction flow paths 26 and 27 are connected to the second circulating flow path 50. Introduction flow path valves I6 and I7 that open and close the introduction flow paths are provided in the introduction flow paths 26 and 27. An introduction flow path 82 that introduces air is connected to the second circulating flow path 50, and an introduction flow path valve A2 that opens and closes the introduction flow path is provided in the introduction flow path 82. A discharge flow path 34 is connected to the second circulating flow path 50. A discharge flow path valve O4 that opens and closes the discharge flow path is provided in the discharge flow path 34.

Pump valves V3, V4, and V5 are provided in the circulating flow path 10. Here, the third circulating flow path valve V3 is also used as a pump valve. Pump valves V6, V7, and V8 are provided in the second circulating flow path 50.

For example, the volume in the second circulating flow path 50 is preferably set to be less than the volume in the circulating flow path 10. Here, the volume in a circulating flow path includes a volume of the circulating flow path when a solution circulates in the circulating flow path. The volume in the circulating flow path 10 is, for example, a volume in the circulating flow path 10 when the valves V1, V2, V3, V4, and V5 are open and the valves I1, I2, I3, I4, I5, O1, O2, O3, A1, and V9 are closed. The volume in the second circulating flow path 50 is, for example, a volume in the second circulating flow path 50 when the valves V6, V7, and V8 are open and the valves I6, I7, O4, A2, and V9 are closed. For example, when the volume in the second circulating flow path 50 is less than the volume in the circulating flow path 10, an amount of solution circulating in the second circulating flow path 50 is less than an amount of solution circulating in the circulating flow path 10. Accordingly, in the fluidic device 200, an amount of chemical (reagent) which is used for detection can be curbed. In the fluidic device 200, when the volume in the second circulating flow path 50 is less than the volume in the circulating flow path 10, it is possible to improve detection sensitivity. For example, when a detection target material is dispersed or resolved in the solution in the second circulating flow path 50, it is possible to improve detection sensitivity by decreasing an amount of solution in the second circulating flow path 50. The volume in the second circulating flow path 50 may be greater than the volume in the circulating flow path 10. In this case, in the fluidic device 200, the amount of solution circulating in the second circulating flow path 50 is greater than the amount of solution circulating in the circulating flow path 10. In this case, in the fluidic device 200, the second circulating flow path 50 may be filled, for example, by transferring the solution circulating in the circulating flow path 10 to the second circulating flow path 50 and adding a measuring solution or a substrate solution thereto.

The circulating flow path 10 and the second circulating flow path 50 are connected to each other via a connecting flow path 100 that connects the circulating flow paths. A connecting flow path valve V9 that opens and closes the connecting flow path 100 is provided in the connecting flow path 100. In the fluidic device 200, a solution is circulated in the circulating flow path 10 in a state in which the connecting flow path valve V9 is closed, and pretreatment is performed. After pretreatment of the solution, the connecting flow path valve V9 is opened and the solution is transferred to the second circulating flow path via the connecting flow path. Thereafter, the connecting flow path valve V9 is closed, the solution is circulated in the second circulating flow path, and a detection reaction is performed. Accordingly, since a pretreated sample is transferred to the second circulating flow path after necessary pretreatment has been performed, it is possible to prevent an unnecessary material from circulating in the second circulating flow path 50. Accordingly, it is possible to curb unnecessary contamination or noise at the time of detection. For example, the circulating flow path 10 and the second circulating flow path 50 do not share any flow path in which a solution can circulate. In the fluidic device 200, since a flow path in which a solution can circulate is not shared, it is possible to decrease a likelihood that residues attached to the wall surface in the circulating flow path 10 and the like will circulated in the second circulating flow path 50 and to decrease contamination at the time of detection in the second circulating flow path 50 due to residues remaining in the circulating flow path 10.

The fluidic device 200 includes introduction inlets for a sample, a reagent, and air which are introduced. The fluidic device 200 includes a first reagent-introduction inlet 10a which is a penetration portion provided at an end of the introduction flow path 21, a sample-introduction inlet 10b which is a penetration portion provided at an end of the introduction flow path 22, a second reagent-introduction inlet 10c which is a penetration portion provided at an end of the introduction flow path 23, a cleaning solution-introduction inlet 10d which is a penetration portion provided at an end of the introduction flow path 24, a transfer solution-introduction inlet 10e which is a penetration portion provided at an end of the introduction flow path 25, and an air-introduction inlet 10f that is provided at an end of the introduction flow path 81.

The first reagent-introduction inlet 10a, the sample-introduction inlet 10b, the second reagent-introduction inlet 10c, the cleaning solution-introduction inlet 10d, the transfer solution-introduction inlet 10e, and the air-introduction inlet 10f are open from the top surface 201b of the substrate plate 201. The first reagent-introduction inlet 10a is connected to a reservoir 215R which will be described later. The sample-introduction inlet 10b is connected to a reservoir 213R which will be described later. The second reagent-introduction inlet 10c is connected to a reservoir 214R which will be described later. The cleaning solution-introduction inlet 10d is connected to a reservoir 212R which will be described later. The transfer solution-introduction inlet 10e is connected to a reservoir 222R which will be described later.

The fluidic device 200 includes a substrate solution-introduction inlet 50a which is a penetration portion provided at an end of the introduction flow path 26, a measuring solution-introduction inlet 50b which is a penetration portion provided at an end of the introduction flow path 27, and an air-introduction inlet 50c that is provided at an end of the introduction flow path 82. The substrate solution-introduction inlet 50a, the measuring solution-introduction inlet 50b, and the air-introduction inlet 50c are open from the top surface 201b of the substrate plate 201. The substrate solution-introduction inlet 50a is connected to a reservoir 224R which will be described later. The measuring solution-introduction inlet 50b is connected to a reservoir 225R which will be described later.

The discharge flow paths 31, 32, and 33 are connected to a waste solution tank 70. The waste solution tank 70 includes an outlet 70a. The outlet 70a is open from the top surface 201b of the substrate plate 201, is connected to, for example, an external suction pump (not illustrated), and is subjected to negative-pressure suction.

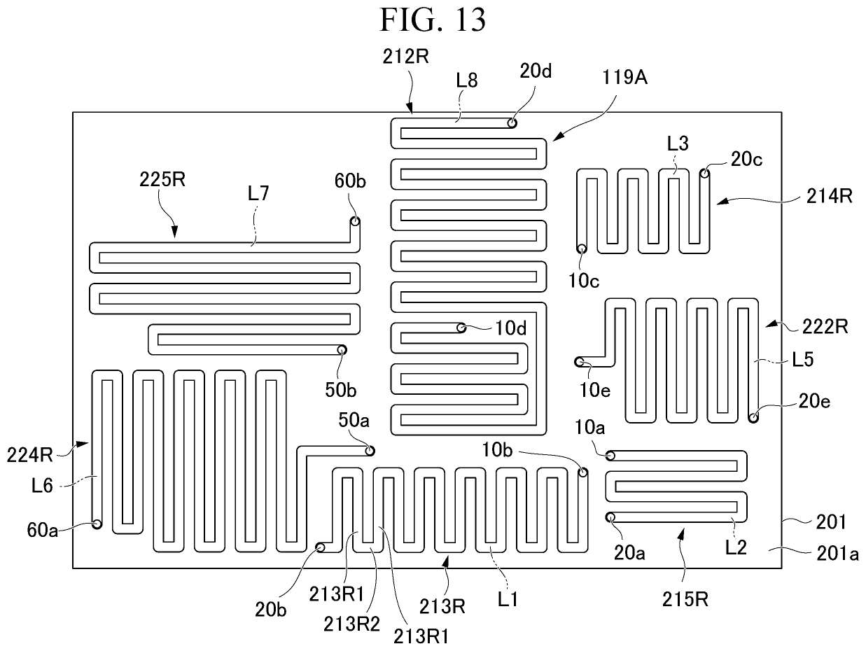

FIG. 13 is a bottom view schematically illustrating a reservoir layer 119A on the bottom surface 201a side of the substrate plate 201. As illustrated in FIG. 13, the reservoir layer 119A includes a plurality of (seven in FIG. 13) flow path type reservoirs 212R, 213R, 214R, 215R, 222R, 224R, and 225R which are disposed in the bottom surface 201a of the substrate plate 201. The reservoirs 212R, 213R, 214R, 215R, 222R, 224R, and 225R can independently accommodate solutions. The reservoirs 212R, 213R, 214R, 215R, 222R, 224R, and 225R are formed of linear recesses which are formed in an in-plane direction of the bottom surface 201a (for example, one direction or a plurality of directions in the in-plane direction of the bottom surface 201a or a direction parallel to the in-plane direction of the bottom surface 201a).

The bottoms of the recesses in the reservoirs 212R, 213R, 214R, 215R, 222R, 224R, and 225R are substantially flush with each other. The recesses in the reservoirs 212R, 213R, 214R, 215R, 222R, 224R, and 225R have the same width. The cross-section of each recess is rectangular, for example, as illustrated in FIG. 5. The cross-section of each of the reservoirs 212R, 213R, 214R, 215R, 222R, 224R, and 225R is set to a size based on the capillary length as described above. In the reservoirs 212R, 213R, 214R, 215R, 222R, 224R, and 225R, for example, the width of each recess is 1.5 mm and the depth is 1.5 mm. The volume of each recess in the reservoirs 212R, 213R, 214R, 215R, 222R, 224R, and 225R is set depending on an amount of solution (a volume of a solution) required for performing a mixing/reaction on the basis of the capillary length. In the reservoirs 212R, 213R, 214R, 215R, 222R, 224R, and 225R, the length is set depending on an amount of solution accommodated therein on the basis of the capillary length. At least two reservoirs out of the reservoirs 212R, 213R, 214R, 215R, 222R, 224R, and 225R in this embodiment have different volumes.

For example, the reservoir 212R has a length of 360 mm and a volume of about 810 μL. The reservoir 213R has a length of 160 mm and a volume of about 360 μL. The reservoirs 214R and 215R have a length of 110 mm and a volume of about 248 μL. The reservoir 222R has a length of 150 mm and a volume of about 338 μL. The reservoir 224R has a length of 220 mm and a volume of about 500 μL. The reservoir 225R has a length of 180 mm and a volume of about 400 μL.

The reservoirs 212R, 213R, 214R, 215R, 222R, 224R, and 225R are formed in a meandering shape in which a linear recess is vertically folded back and extends in a predetermined direction. For example, regarding the reservoir 213R, the reservoir 213R is formed in a meandering shape including a plurality of (thirteen in FIG. 13) first straight portions 213R1 which are disposed in parallel to a predetermined direction (a right-left direction in FIG. 13) and second straight portions 213R2 in which connecting portions between the ends of the neighboring first straight portions 213R1 are alternately and repeatedly connected at one end and the other end of the first straight portions 213R1. For example, the reservoirs 212R, 214R, 215R, 222R, 224R, and 225R are formed in a meandering shape similarly to the reservoir 213R.

One end of the reservoir 212R is connected to the cleaning solution-introduction inlet (the penetration portion) 10d penetrating the substrate plate 201 in the thickness direction thereof. The other end of the reservoir 212R is connected to an atmospheric open portion 20d. The atmospheric open portion 20d penetrates the substrate plate 201 in the thickness direction thereof. One end of the reservoir 213R is connected to the test sample-introduction inlet (the penetration portion) 10b penetrating the substrate plate 201 in the thickness direction thereof. The other end of the reservoir 213R is connected to an atmospheric open portion 20b. The atmospheric open portion 20b penetrates the substrate plate 201 in the thickness direction thereof. One end of the reservoir 214R is connected to the second reagent-introduction inlet (the penetration portion) 10c penetrating the substrate plate 201 in the thickness direction thereof. The other end of the reservoir 214R is connected to an atmospheric open portion 20c. The atmospheric open portion 20c penetrates the substrate plate 201 in the thickness direction thereof. One end of the reservoir 215R is connected to the first reagent-introduction inlet (the penetration portion) 10a penetrating the substrate plate 201 in the thickness direction thereof. The other end of the reservoir 215R is connected to an atmospheric open portion 20a. The atmospheric open portion 20a penetrates the substrate plate 201 in the thickness direction thereof. One end of the reservoir 222R is connected to the transfer solution-introduction inlet (the penetration portion) 10e penetrating the substrate plate 201 in the thickness direction thereof. The other end of the reservoir 222R is connected to an atmospheric open portion 20e. The atmospheric open portion 20e penetrates the substrate plate 201 in the thickness direction thereof. One end of the reservoir 224R is connected to the substrate solution-introduction inlet (the penetration portion) 50a penetrating the substrate plate 201 in the thickness direction thereof. The other end of the reservoir 224R is connected to an atmospheric open portion 60a. The atmospheric open portion 60a penetrates the substrate plate 201 in the thickness direction thereof. One end of the reservoir 225R is connected to the measuring solution-introduction inlet (the penetration portion) 50b penetrating the substrate plate 201 in the thickness direction thereof. The other end of the reservoir 225R is connected to an atmospheric open portion 60b. The atmospheric open portion 60b penetrates the substrate plate 201 in the thickness direction thereof. Air holes (not illustrated) communicating with the atmospheric open portions 20a, 20b, 20c, 20d, 20e, 60a, and 60b are formed to penetrate the upper plate 6 in the thickness direction thereof.

As illustrated in FIG. 13, for example, 800 μL of a cleaning solution L8 is accommodated as a solution in the reservoir 212R. For example, 300 μL of a test sample solution L1 including a sample material is accommodated as a solution in the reservoir 213R. For example, 200 μL of a second reagent solution L3 including a marker material (a detection assisting material) is accommodated as a solution in the reservoir 214R. For example, 200 μL of a first reagent solution L2 including carrier particles is accommodated as a solution in the reservoir 215R. For example, 300 μL of a transfer solution L5 is accommodated as a solution in the reservoir 222R. For example, 500 μL of a substrate solution L6 is accommodated as a solution in the reservoir 224R. For example, 400 μL of a measuring solution L7 is accommodated as a solution in the reservoir 225R. The capacities of the reservoirs can be easily adjusted by changing at least one of the width, the depth, and the length.

For example, in a method of manufacturing the fluidic device 200, similarly to the above-mentioned fluidic device 100A, the fluidic device 200 is manufactured by forming the reservoir layer 119A and the reaction layer 119B in the substrate plate 201, installing various types of valves in the upper plate, and then bonding the upper plate, the lower plate, and the substrate plate 201 to be integrated into a stacked state by a bonding means such as adhesion. In the manufactured fluidic device 200, a predetermined solution is injected into the reservoirs 212R, 213R, 214R, 215R, 222R, 224R, and 225R via the air holes. For example, an amount of solution which is injected doubles the amount of solution which is used for detection of a sample material which will be described later. A suction pressure at the time of injection of a solution is, for example, 5 kPa.

(Mixing Method, Capturing Method, Detection Method Using Fluidic Device 200)

The mixing method, the capturing method, and the detection method using the fluidic device 200 having the above-mentioned configuration will be described below. Since the fluidic device 200 includes the circulation type mixer 1d, the mixing method, the capturing method, and the detection method using the circulation type mixer 1d will be described below. In the detection method according to this embodiment, an antigen (such as a sample material or a biomolecule) which is a detection target included in a test sample is detected by an immune reaction and an enzyme reaction.

(Introduction Process and Partitioning Process)

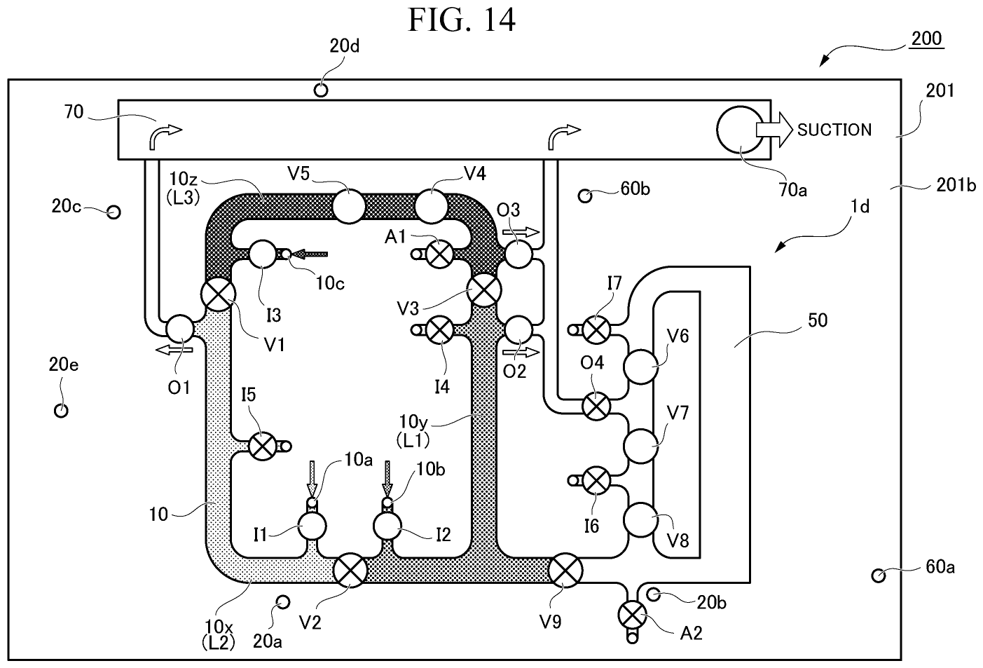

First, as illustrated in FIG. 14, the first circulating flow path valve V1, the second circulating flow path valve V2, the third circulating flow path valve V3, and the introduction flow path valves I5, I4, and A1 are closed. Accordingly, the circulating flow path 10 is partitioned into a flow path 10x, a flow path 10y, and a flow path 10z.

Subsequently, the first reagent solution L2 including carrier particles is introduced into the flow path 10x from the first reagent-introduction inlet 10a connected to the reservoir 215R of the reservoir layer 119A, the sample solution L1 including a sample material is introduced into the flow path 10y from the sample solution-introduction inlet 10b connected to the reservoir 213R, and the second reagent solution L3 including a marker material (a detection assisting material) is introduced into the flow path 10z from the second reagent-introduction inlet 10c connected to the reservoir 214R.

Introduction of the sample solution L1, the second reagent solution L3, and the first reagent solution L2 from the reservoirs 213R, 214R, and 215R is performed by performing negative-pressure suction from the outlet 70a of the waste solution tank 70 in a state in which the waste solution valves O1, O2, and O3 and the introduction flow path valves I2 and I3 are open. At the time of introduction of the sample solution L1, the second reagent solution L3, and the first reagent solution L2, since the reservoirs 213R, 214R, and 215R are formed of linear recesses meandering in the in-plane direction, the capillary force has a greater influence on the sample solution L1, the second reagent solution L3, and the first reagent solution L2 than the acceleration which includes the gravity and which is applied to the sample solution L1, the second reagent solution L3, and the first reagent solution L2, and the sample solution L1, the second reagent solution L3, and the first reagent solution L2 are held in the reservoirs 213R, 214R, and 215R by the capillary force, the sample solution L1, the second reagent solution L3, and the first reagent solution L2 can be easily introduced into the flow path 10y, the flow path 10z, and the flow path 10x without allowing bubbles remaining on the opposite sides of the solution-introduction inlets 10b, 10c, and 10a of the reservoirs 213R, 214R, and 215R to precede the solutions.

In this embodiment, the sample solution L1 includes an antibody which is a detection target (a sample material). Examples of the sample solution include a body fluid such as blood, urine, saliva, blood plasma, or serum, a cellular extract, and a tissue-crushed solution. In this embodiment, magnetic particles are used as carrier particles included in the first reagent solution L2. An antibody A which is singularly coupled to an antigen (a sample material) which is a detection target is fixed to the surfaces of magnetic particles. In this embodiment, the second reagent solution L3 contains an antibody B which is singularly coupled to an antigen which is a detection target. An alkali phosphatase (a detection assisting material, an enzyme) is fixed to the antibody B to mark the antibody.

(Mixing Process)

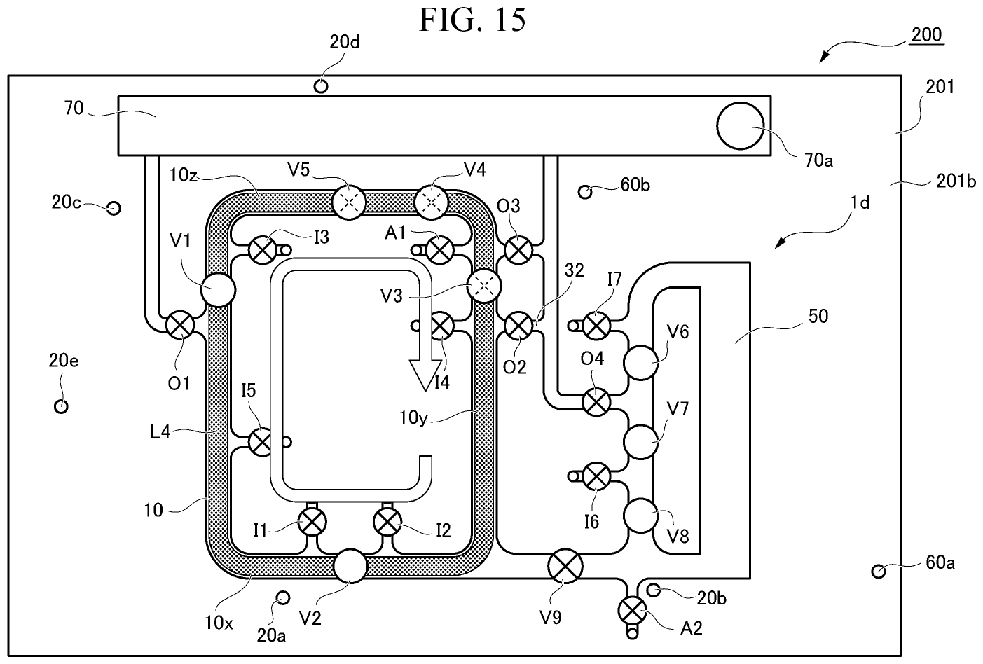

Subsequently, as illustrated in FIG. 15, the introduction flow path valves I1, I2, and I3 are closed. Accordingly, communication with a flow path connected to the circulating flow path 10 is cut off and the circulating flow path 10 is closed. The first circulating flow path valve V1, the second circulating flow path valve V2, and the third circulating flow path valve V3 are opened, the pump valves V3, V4, and V5 are operated, the first reagent solution L2 (a first reagent), the sample solution L1 (a sample), and the second reagent solution L3 (a second reagent) are circulated in the circulating flow path 10 to mix the solutions, and a mixed solution L4 is obtained. By mixing the first reagent solution L2, the sample solution L1, and the second reagent solution L3, an antigen is coupled to the antibody A fixed to the carrier particles and the antibody B to which an enzyme is fixed is coupled to the antigen. Accordingly, a carrier particle-antigen-enzyme complex (a carrier particle-sample material-detection assisting material complex, a first complex) is formed.

(Magnet Installing Process and Capturing Process)

The capturing portion 40 (see FIG. 12) includes a magnet installing portion 41 in which a magnet capturing magnetic particles can be installed. A magnet is installed in the magnet installing portion 41 to enter a capturable state in which the magnet is close to the circulating flow path. In this state, the pump valves V3, V4, and V5 are operated to circulate a solution including the carrier particle-antigen-enzyme complex (the first complex) in the circulating flow path 10 and to cause the capturing portion 40 to capture the carrier particle-antigen-enzyme complex. The carrier particle-antigen-enzyme complex flows in one direction or two directions in the circulating flow path and circulates or reciprocates in the circulating flow path. In FIG. 15, a state in which the carrier particle-antigen-enzyme complex circulates in one direction. The complex is captured on the inner wall surface of the circulating flow path 10 in the capturing portion 40 and is separated from a liquid component.

(Cleaning Process)

The introduction flow path valve A1 and the discharge flow path valve O2 are opened, the third circulating flow path valve V3 is closed, negative-pressure suction from the outlet 70a is performed, and air is introduced into the circulating flow path 10 from the air-introduction inlet 10f via the introduction flow path 81. Accordingly, a liquid component (a waste solution) separated from the carrier particle-antigen-enzyme complex is discharged from the circulating flow path 10 via the discharge flow path 32. The waste solution is stored in the waste solution tank 70. By closing the third circulating flow path valve V3, air is efficiently introduced into the circulating flow path 10 as a whole.

Thereafter, the discharge flow path valve O2 and the third circulating flow path valve V3 are closed, the introduction flow path value I4 and the discharge flow path valve O3 are opened, and negative-pressure suction from the outlet 70a is performed. Accordingly, a cleaning solution L8 is introduced into the circulating flow path 10 from the reservoir 212R via the cleaning solution-introduction inlet 10d and the introduction flow path 24. By closing the third circulating flow path valve V3, the cleaning solution L8 is introduced into the circulating flow path 10 to fill the circulating flow path 10. At the time of introduction of the cleaning solution L8, since the reservoir 212R is formed of a linear recess meandering in the in-plane direction, the capillary force has a greater influence on the cleaning solution L8 than the acceleration which includes the gravity and which is applied to the cleaning solution L8, and the cleaning solution L8 is held in the reservoir 212R by the capillary force, the cleaning solution L8 can be easily introduced into the circulating flow path 10 without allowing bubbles remaining on the opposite side of the cleaning solution-introduction inlet 10d of the reservoir 212R to precede the solutions. Thereafter, the third circulating flow path valve V3 is opened, the introduction flow path value I4 and the discharge flow path valve O2 are closed, the circulating flow path 10 is cut off, the pump valves V3, V4, and V5 are operated to circulate the cleaning solution L8 in the circulating flow path 10 and to clean the carrier particles.

Subsequently, the introduction flow path valve A1 and the discharge flow path valve O2 are opened, the third circulating flow path valve V3 is closed, negative-pressure suction from the outlet 70a is performed, and air is introduced into the circulating flow path 10 from the air-introduction inlet 10f via the introduction flow path 81. Accordingly, the cleaning solution is discharged from the circulating flow path 10, and the antibody B which has not formed the carrier particle-antigen-enzyme complex is discharged from the circulating flow path 10. Introduction and discharge of the cleaning solution may be performed a plurality of times. By repeatedly introducing the cleaning solution, performing cleaning, and discharging the solution after cleaning, it is possible to enhance removal efficiency of impurities.

(Transfer Process)

The introduction flow path valve I5 and the discharge flow path valve O3 are opened, the discharge flow path valve O2 and the third circulating flow path valve V3 are closed, negative-pressure suction from the outlet 70a is performed, and the transfer solution L5 is introduced into the circulating flow path 10 from the reservoir 222R via the transfer solution-introduction inlet 10e and the introduction flow path 25. The introduction flow path value I5 and the discharge flow path valve O2 are opened, the discharge flow path valve O3 and the third circulating flow path valve V3 are closed, negative-pressure suction from the outlet 70a is performed, and the transfer solution L5 is introduced into the circulating flow path 10 from the transfer solution-introduction inlet 10e connected to the reservoir 222R via the introduction flow path 25. At the time of introduction of the transfer solution L5, since the reservoir 222R is formed of a linear recess meandering in the in-plane direction, the capillary force has a greater influence on the transfer solution L5 than the acceleration which includes the gravity and which is applied to the transfer solution L5, and the transfer solution L5 is held in the reservoir 222R by the capillary force, the transfer solution L5 can be easily introduced into the circulating flow path 10 without allowing bubbles remaining on the opposite side of the transfer solution-introduction inlet 10e of the reservoir 222R to precede the solutions.

Subsequently, the third circulating flow path valve V3 is opened, the introduction flow path value I5 and the discharge flow path valves O2 and O3 are closed, and the circulating flow path 10 is cut off. The magnet is detached from the magnet installing portion 41 and is separated away from the circulating flow path to enter a released state, and the carrier particle-antigen-enzyme complex captured on the inner wall surface of the circulating flow path 10 in the capturing portion 40 is released. The pump valves V3, V4, and V5 are operated, the transfer solution is circulated in the circulating flow path 10, and the carrier particle-antigen-enzyme complex is dispersed in the transfer solution.

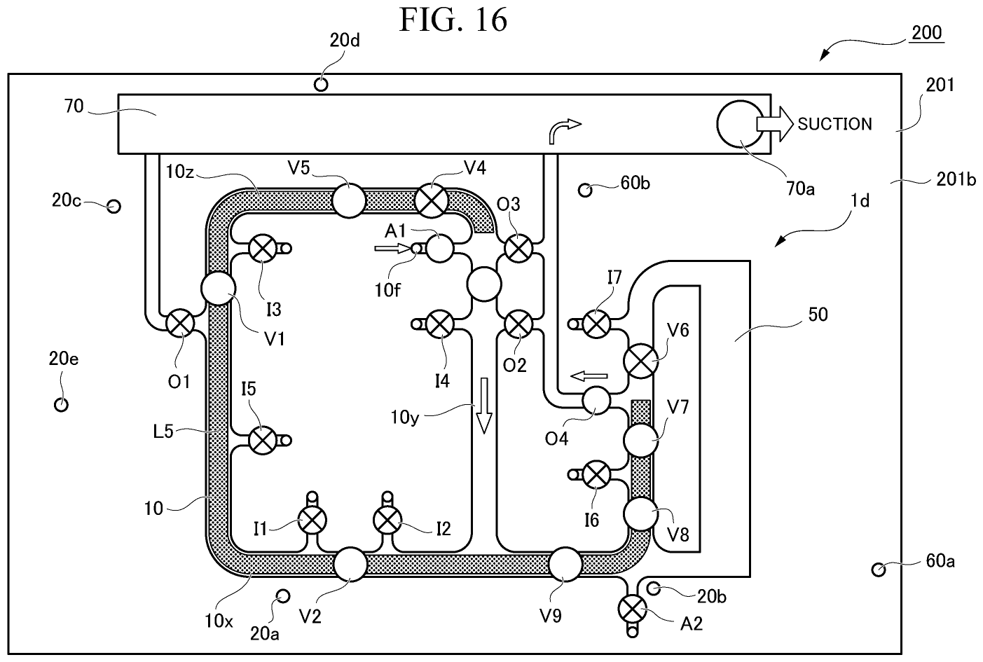

Subsequently, as illustrated in FIG. 16, the introduction flow path valve A1, the connecting flow path valve V9, and the discharge flow path valve O4 are opened, negative-pressure suction from the outlet 70a is performed, and air is introduced into the circulating flow path 10 from the air-introduction inlet 10f via the introduction flow path 81. The transfer solution including the carrier particle-antigen-enzyme complex is extruded by the air and the transfer solution L5 is introduced into the second circulating flow path 50 via the connecting flow path 100. At this time, when the valve V6 is closed and the transfer solution L5 reaches a connecting portion between the discharge flow path 34 and the second circulating flow path 50, the valve V7 is closed and the second circulating flow path 50 is filled with the transfer solution. The carrier particle-antigen-enzyme complex is transferred to the second circulating flow path 50.

(Detection Process)

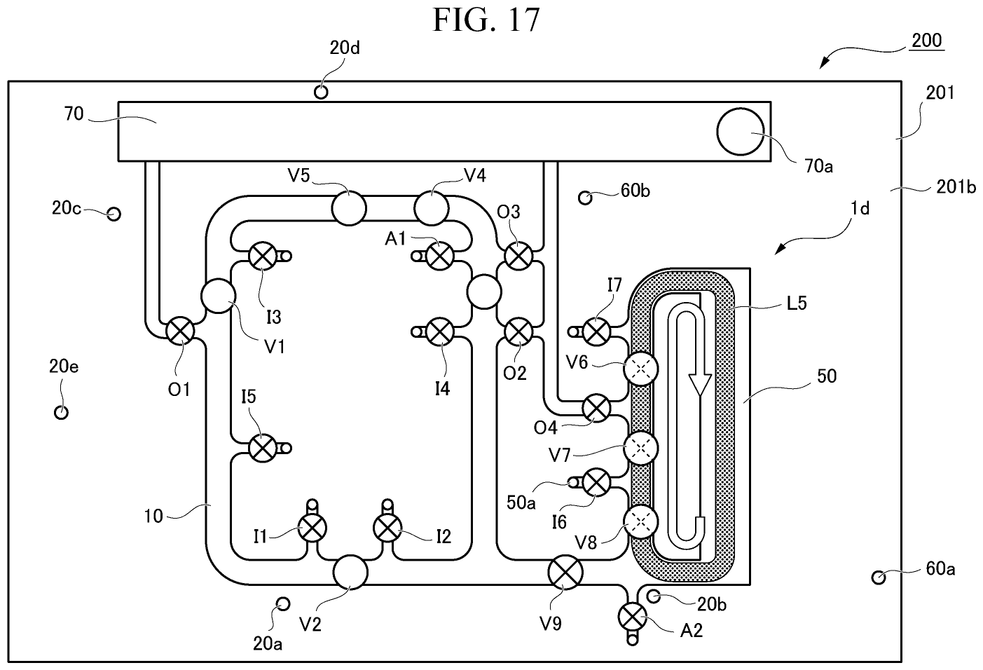

After transferring of the transfer solution to the second circulating flow path 50 has been completed, as illustrated in FIG. 17, the connecting flow path valve V9 and the discharge flow path valve O4 are closed to cut off the second circulating flow path 50, the pump valves V6, V7, and V8 are operated to circulate the transfer solution L5 including the carrier particle-antigen-enzyme complex in the second circulating flow path 50, and the carrier particle-antigen-enzyme complex is captured by the capturing portion 42 (see FIG. 12).

The introduction flow path valve A2 and the discharge flow path valve O4 are opened, negative-pressure suction from the outlet 70a is performed, and air is introduced into the second circulating flow path 50 from the air-introduction inlet 50c via the introduction flow path 82. Accordingly, the liquid component (the waste solution) of the transfer solution L5 separated from the carrier particle-antigen-enzyme complex is discharged from the second circulating flow path 50 via the discharge flow path 34. The waste solution is stored in the waste solution tank 70. At this time, air is efficiently introduced into the second circulating flow path 50 as a whole by closing the valve V6 or the valve V7.

The introduction flow path valve I6 and the discharge flow path valve O4 are opened, the valve V7 is closed, negative-pressure suction from the outlet 70a is performed, and the substrate solution L6 is introduced into the second circulating flow path 50 from the reservoir 224R via the substrate solution-introduction inlet 50a and the introduction flow path 26. The substrate solution L6 includes 3-(2′-spiroadamantane)-4-methoxy-4-(3″-phosphoryloxy)phenyl-1,2-dioxetane (AMPPD) or 4-Aminophenyl Phosphate (pAPP) which serves as a substrate of an alkali phosphatase (an enzyme). At the time of introduction of the substrate solution L6, since the reservoir 224R is formed of a linear recess meandering in the in-plane direction, the capillary force has a greater influence on the substrate solution L6 than the acceleration which includes the gravity and which is applied to the substrate solution L6, and the substrate solution L6 is held in the reservoir 224R by the capillary force, the substrate solution L6 can be easily introduced into the second circulating flow path 50 without allowing bubbles remaining on the opposite side of the substrate solution-introduction inlet 50a of the reservoir 224R to precede the solutions.

The discharge flow path valve O4 and the introduction flow path value I6 are closed to cut off the second circulating flow path 50, the pump valves V6, V7, and V8 are operated to circulate the substrate solution in the second circulating flow path 50, and the substrate and the carrier particle-antigen-enzyme complex are caused to react with each other.

Through the above-mentioned operations (the detection method and the like), an antigen which is a detection target included in a sample can be detected as a chemiluminescent signal, an electrochemical signal, or the like. In this way, the detecting portion 60 and the capturing portion 42 may not be used in combination and the capturing portion is not necessarily provided in the second circulating flow path 50.

The detection method according to this embodiment can also be applied to analysis of a biological sample, in-vitro diagnosis, or the like.

Through the above-mentioned routine, it is possible to detect a sample material using the fluidic device 200. In the fluidic device 200 according to this embodiment, similarly to the fluidic devices 100A according to the first to third embodiments, since the size of the cross-section of each of the reservoirs 212R, 213R, 214R, 215R, 222R, 224R, and 225R is set on the basis of the capillary length, bubbles in the reservoirs 212R, 213R, 214R, 215R, 222R, 224R, and 225R can be prevented from reaching the circulating flow path 10 or the second circulating flow path 50 earlier than the solutions and being mixed thereinto even when the fluidic device 100A is inclined with respect to the horizontal plane. Accordingly, in the fluidic device 200 according to this embodiment, supply of solutions from the reservoirs 212R, 213R, 214R, 215R, 222R, 224R, and 225R to the circulating flow path 10 or the second circulating flow path 50 can be easily performed without mixing bubbles and thus it is possible to improve detection accuracy of the sample material.

In this embodiment, an example in which the substrate solution L6 and the measuring solution L7 are introduced, circulated, and detected by the detecting portion 60 as a solution which is circulated in the second circulating flow path to detect a sample material is described. However, the solutions may be one kind of solution. A plurality of quantification sections may be provided in the second circulating flow path 50 and solutions which are introduced into and quantified in the individual sections and which are circulated and mixed may be used.

In the above embodiments, the configuration or the detection method of a fluidic device using an antigen-antibody reaction has been described above, and may also be applied to a reaction using hybridization.

While embodiments of the invention have been described above with reference to the accompanying drawings, the invention is not limited to the embodiments. All shapes, combinations, and the like of the constituent members described in the above embodiments are only examples and can be modified in various forms on the basis of a design request or the like without departing from the gist of the invention.

For example, the cross-section of each of the reservoirs 29A, 29B, 29C, 212R, 213R, 214R, 215R, 222R, 224R, and 225R in the above embodiments are rectangular, but the invention is not limited to the configuration and the cross-section may have, for example, a circular shape or a tapered shape which decreases in width toward the bottom surface as illustrated in FIG. 4. When this configuration is employed, for example, when the substrate plate 9 is manufactured by injection molding, it is possible to decrease mold release resistance and to improve moldability.

In the above embodiments, a configuration in which a plurality of reservoirs have the same width and the same depth has been described above, but the invention is not limited to this configuration. For example, the width and the depth of each of a plurality of reservoirs may be set to different values depending on fluid flow characteristics of a solution which is accommodated. For example, when solutions are introduced into a circulating flow path by comprehensive negative-pressure suction from the plurality of reservoirs, the width and the depth based on fluid flow characteristics (fluid flow resistance or the like) of a solution for each reservoir may be set such that different types of solutions are introduced into the circulating flow path at the same timing.

Introduction of various types of solutions into the circulating flow path from the reservoirs does not need to be performed only once but may be divisionally performed a plurality of times. When solutions are divisionally introduced a plurality of times, an amount of solution for each time can be quantified by controlling an operation time of a solution transfer pump or providing a solution sensor and detecting passing of the head of a gas-solution interface through a quantification zone.

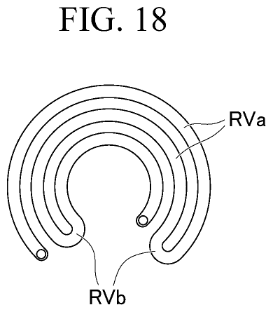

In the above embodiments, the reservoirs 29A, 29B, 29C, 212R, 213R, 214R, 215R, 222R, 224R, and 225R have a shape in which a linear recess meanders, but may include a curved flow path which is a flow path with a non-straight shape. Examples of a reservoir including a curved flow path include a configuration in which a U-shaped, W-shaped, or C-shaped flow path is included or a configuration in which a plurality of (three in FIG. 18) first arc-shaped portion RVa which are concentrically formed and second arc-shaped portions RVb which alternately and repeatedly connect connecting portions of the neighboring first arc-shaped portions RVa at one end and the other end in the circumferential direction of the first arc-shaped portions RVa are included, as illustrated in FIG. 18. The reservoir of a curved shape is not limited to an arc shape, but may have a spiral shape in which a distance from an axis perpendicular to one surface of the substrate increases gradually with respect to the axis. The size of a cross-section of a reservoir including a flow path of a curved shape which is a flow path of a non-straight shape can be set on the basis of the capillary length.

In the above embodiments, a configuration in which the reservoir layer 19A is disposed in the bottom surface 9a of the substrate plate 9 and the reaction layer 19B is disposed in the top surface 9b of the substrate plate 9 and a configuration in which the reservoir layer 119A is disposed in the bottom surface 201a of the substrate plate 201 and the reaction layer 119B is disposed in the top surface 201b of the substrate plate 201 have been described above, but the invention is not limited to the configurations. For example, when the reaction layer 19B is disposed in the top surface 9b of the substrate plate 9, a configuration in which the reservoir layer is disposed in the top surface of the lower plate 8 or a configuration in which the reservoir layer is disposed in the top surface of the lower plate 8 and the bottom surface 9a of the substrate plate 9 may be employed. For example, when the reservoir layer 119A is disposed in the bottom surface 201a of the substrate plate 201, a configuration in which a reaction layer is disposed in the bottom surface of the upper plate 6, a configuration in which the reaction layer is formed in a substrate other than the upper plate 6 and the substrate plate 201, or a configuration in which the reaction layer is disposed in the bottom surface of the upper plate 6 and the top surface 201b of the substrate plate 201 may be employed.

### DESCRIPTION OF THE REFERENCE SYMBOLS

9, 201 . . . Substrate plate
9a, 201a . . . Bottom surface (one surface)
9b, 201b . . . Top surface (other surface)
10 . . . First circulating flow path (circulating flow path)
10a, 10b, 10c, 10d, 10e, 50a, 50b . . . Solution introduction inlet (penetration portion)
19A, 119A . . . Reservoir layer
19B, 119B . . . Reaction layer
29A, 29B, 29C . . . Reservoir
39A, 39B, 39C . . . Penetration portion (penetration flow path)
40, 42 . . . Capturing portion
50 . . . Second circulating flow path (circulating flow path)
100A, 200 . . . Fluidic device
212R, 213R, 214R, 215R, 222R, 224R, 225R . . . Reservoir
S . . . Solution

1. A fluidic device comprising:
a flow path into which a solution is introduced; and
a reservoir in which the solution is accommodated and which supplies the solution to the flow path,
wherein a length of the reservoir in a direction in which the solution flows toward the flow path is greater than a width perpendicular to the length, and
wherein a width and a depth of the reservoir are formed in a size based on a capillary length which is calculated based on a surface tension and a density of the solution and acceleration which includes gravity and which is applied to the solution.

2. The fluidic device according to claim 1,
wherein the width of the reservoir is formed such that a radius of an inscribed circle of the reservoir is less than the capillary length.

3. The fluidic device according to claim 2,
wherein, when the surface tension is defined as γ (N/m), the density is defined as ρ (kg/m³), the acceleration which includes gravity and which is applied to the solution is defined as G (m/s²), and the radius is defined as r (m), a relationship 0.05×10⁻³<r<(γ/(ρ×G))^{1/2} is satisfied.

4. The fluidic device according to claim 3,
wherein, when a reagent length of the solution is defined as L (m), a flow path wetted perimeter length is defined as Wp (m), and a sectional area of the reservoir is defined as A (m²), a relationship L≤(2×γ×Wp)/(ρ×A×G) is satisfied.

5. The fluidic device according to claim 1,
wherein the reservoir includes a holding region in which the solution is held in the reagent length, and
wherein both sides in a length direction of the holding area include a diameter-increased portion in which the flow path wetted perimeter length increases gradually outward in the length direction.

6. (canceled)

7. The fluidic device according to claim 1,
wherein a size of the width of the reservoir is a size in which a bubble does not move to precede the solution.

8-18. (canceled)

19. The fluidic device according to claim 1, comprising:
a substrate plate having a first surface on which the flow path into which the solution is introduced is formed; and
a second substrate plate that is stacked on and bonded to the substrate plate such that the second substrate plate faces the first surface,
wherein at least part of the flow path and at least part of the reservoir overlap each other when seen in in a direction in which the substrate plate and the second substrate plate are stacked.

20. The fluidic device according to claim 19, comprising
a second flow path that is disposed in a part in which the at least part of the flow path and the at least part of the reservoir overlap each other when seen in a direction in which the substrate plate and the second substrate plate are stacked and connects the flow path to the reservoir.

21. The fluidic device according to claim 19,
wherein the reservoir is formed on a second surface opposite to the first surface of the substrate plate, and
wherein the fluidic device comprises a third substrate plate that is bonded to the substrate plate such that the third substrate plate faces the second surface.

22. The fluidic device according to claim 1,
wherein the flow path is formed on one surface of a substrate plate and performs quantification or mixing of the solution, and
wherein the reservoir is formed to be parallel to the other surface opposite to the one surface of the substrate plate.

23. The fluidic device according to claim 1,
wherein the reservoir is formed of a recess which is disposed on one surface of a substrate plate and which is formed in an in-plane direction of the one surface.

24. The fluidic device according to claim 23, comprising
a reservoir layer including a plurality of the reservoirs,
wherein the plurality of reservoirs are able to independently accommodate the solution.

25. The fluidic device according to claim 23,
wherein the plurality of reservoirs have a different volume of the recess from each other.

26. The fluidic device according to claim 23,
wherein the reservoirs are configured in a state in which the solution is accommodated therein.

27. The fluidic device according to claim 23, comprising
a reaction layer that is disposed on the other surface other than the one surface of the substrate plate and causes a sample material to react using the solution supplied from the reservoir.

28. The fluidic device according to claim 27,
wherein the reaction layer includes a circulating flow path in which the solution including the sample material circulates.

29. (canceled)

30. (canceled)

31. The fluidic device according to claim 23,
wherein the recesses are formed in a linear shape with the same width.

32. The fluidic device according to claim 23,
wherein one end of the recess is connected to a penetration portion penetrating the substrate plate.

33. The fluidic device according to claim 32,
wherein the other end of the recess is connected to an atmospheric open portion.

34. The fluidic device according to claim 23,
wherein the reservoir is formed in a meandering shape including a plurality of first straight portions which are disposed to be parallel to a predetermined direction and a second straight portion that extends in a direction crossing the first straight portions and repeatedly connects connection portions between ends of the neighboring first straight portions alternately at one end and the other end of the first straight portions.

35-39. (canceled)
